(19) United States
(12) Patent Application Publication
(10) Pub. No.: US 2024/0215221 A1
(43) Pub. Date: Jun. 27, 2024

(54) MICROELECTRONIC DEVICES, AND RELATED MEMORY DEVICES, AND ELECTRONIC SYSTEMS

(71) Applicant: Micron Technology, Inc., Boise, ID (US)

(72) Inventor: Fatma Arzum Simsek-Ege, Boise, ID (US)

(21) Appl. No.: 18/522,120

(22) Filed: Nov. 28, 2023

Related U.S. Application Data
(60) Provisional application No. 63/477,028, filed on Dec. 23, 2022.

(51) Int. Cl. H10B 12/00

(52) U.S. Cl. CPC H10B 12/30; H10B 12/03; H10B 12/05

(57) ABSTRACT

A microelectronic device includes first memory array region and second memory array regions, each comprising vertical stacks of dynamic random access memory (DRAM) cells. A staircase region is between the first memory array region and the second memory array region and comprises a staircase structure comprising a vertical stack of first conductive structures horizontally extending through the staircase region in a first direction, the first conductive structures configured to be in contact with the DRAM cells of the first memory array region and DRAM cells of the second memory array region, and sub-staircase structures individually comprising second conductive structures horizontally extending from the vertical stack of first conductive structures in a second direction. Horizontally neighboring sub-staircase structures are substantially evenly horizontally spaced from one another in the first direction. Related microelectronic devices, memory devices, and electronic systems are also described.

### CROSS-REFERENCE TO RELATED APPLICATION

This application claims the benefit under 35 U.S.C. § 119(e) of U.S. Provisional Patent Application Ser. No. 63/477,028, filed Dec. 23, 2022, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of microelectronic devices including a staircase structure between horizontally neighboring memory array regions, the staircase structure operatively associated with vertically stacked memory cells of the memory array regions, and to related memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

As the size of the memory cells has decreased, the density and complexity of the memory array have increased. With the increased density of memory cells within the memory array, the density of the conductive interconnect structures configured to facilitate operation of the memory cells has also increased. For example, the spacing between neighboring conductive interconnect structures has decreased with the increased density of memory cells of the memory array. However, the increased density of the conductive interconnect structures presents difficulties in adequately forming conductive interconnect structures in electrical communication with the memory cells. In addition, as the density of memory cells has increased, the amount of area occupied by electrical interconnects between components of the memory cells has increased.

### BRIEF DESCRIPTION OF THE DRAWINGS

FIG. 1A through FIG. 1Z are simplified partial top-down views (FIG. 1A, FIG. 1E, FIG. 1J, FIG. 1L, FIG. 1O, FIG. 1Q, FIG. 1T, and FIG. 1W), simplified partial cross-sectional views (FIG. 1B through FIG. 1D, FIG. 1F through FIG. 1I, FIG. 1K, FIG. 1M, FIG. 1N, FIG. 1P, FIG. 1R, FIG. 1S, FIG. 1U, FIG. 1V, FIG. 1X, and FIG. 1Y), and a simplified partial perspective view (FIG. 1Z) illustrating a method of forming a first microelectronic device structure (e.g., a memory device, such as a 3D DRAM memory device), in accordance with embodiments of the disclosure;

FIG. 2A through FIG. 2E are a simplified partial top-down view (FIG. 2A) and simplified partial cross-sectional views (FIG. 2B through FIG. 2E) illustrating a method of forming a microelectronic device from the first microelectronic device structure and a second microelectronic device structure, in accordance with embodiments of the disclosure; and

FIG. 3 is a schematic block diagram of an electronic system, in accordance with an embodiment of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for case of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

According to embodiments described herein, a microelectronic device includes a microelectronic device structure including array regions, each array region comprising vertical stacks of memory cells and vertical stack structures comprising vertically spaced conductive structures horizontally extending through the array region. The vertical stacks of memory cells individually comprise a vertical stack of storage devices, each storage device in contact with an access device of a vertical stack of access devices. The vertical stack structures individually horizontally extend from a first array region, through a staircase region, and to a second array region. The staircase region horizontally intervenes between the first array region and the second array region. The staircase region includes staircase structures shared between the vertical stacks of memory cells of the first array region and the vertical stacks of memory cells of the second array region. Each staircase structure individually comprises a vertical stack of vertically spaced first conductive structures horizontally extending through the first array region, the staircase region, and the second array region. In use and operation (e.g., responsive to an applied voltage) the first conductive structures are configured to be in electrical communication with the vertical stacks of memory cells of the first array region and the vertical stacks of memory cells of the second array region (e.g., the vertical stacks of access devices of the first array region and the vertical stacks of access devices of the second array region). Each staircase structure further comprises sub-staircase structures horizontally extending from the vertical stack of first conductive structures (e.g., substantially perpendicular to the vertical stack of first conductive structures). The sub-staircase structures comprise second conductive structures in contact with (and configured to be in electrical communication with, such as during use and operation) the first conductive structures. Each sub-staircase structure comprises steps defined at horizontal edges of the second conductive structures. The steps of each sub-staircase structure of a staircase structure are vertically offset from one another.

Conductive contact structures are contact with the second conductive structures at the steps. The microelectronic device further comprises a second microelectronic device structure is attached to the first microelectronic device structure. The second microelectronic device structure comprises a sub word line driver region comprising sub word line drivers directly vertically above and within horizontal boundaries of the staircase region. The sub word line drivers may be configured to be in electrical communication with the vertical stacks of memory cells of the first array region and the vertical stacks of memory cells of the second array region by means of the conductive contact structures. The sub word line drivers are configured to provide a drive voltage to, for example, the vertical stacks of access devices of each of the first array region and the second array region. Since each step is in contact with a first conductive structure of the vertical stack that extends through the first array region and the second array region, application of a voltage to the conductive contact structure of the step provides a drive voltage to memory cells of the first array region simultaneously to memory cells of the second array region. Accordingly, the memory cells of the first array region and the second array region may be driven (e.g., a voltage may be applied thereto) by applying a voltage to conductive contact structures horizontally between the first array region and the second array region.

The location of the staircase region horizontally between the first array region and the second array region reduces a horizontal area occupied by the staircase structures and facilitates increasing a density of the vertical stacks of memory cells within a given area. In addition, forming the staircase structures to include the sub-staircase structures reduces the complexity of forming the steps, such as by reducing the quantity of different material compositions that are removed during patterning of the staircase structure compared to conventional microelectronic devices.

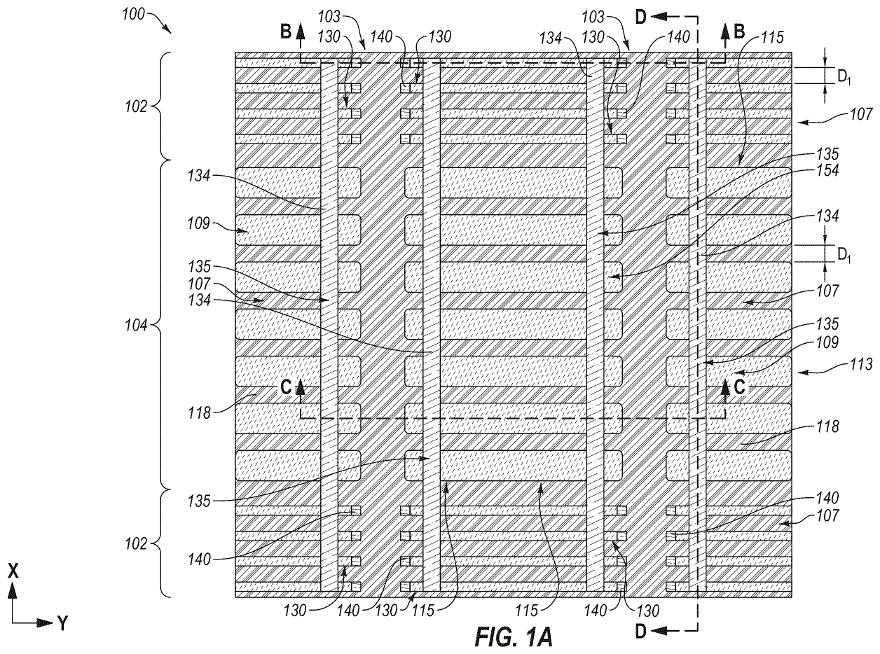

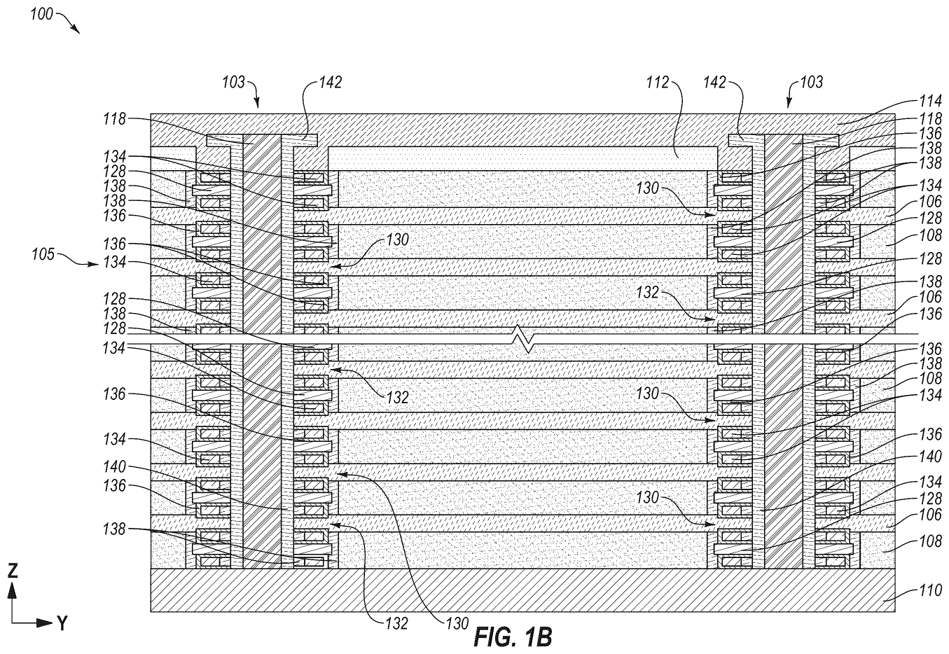

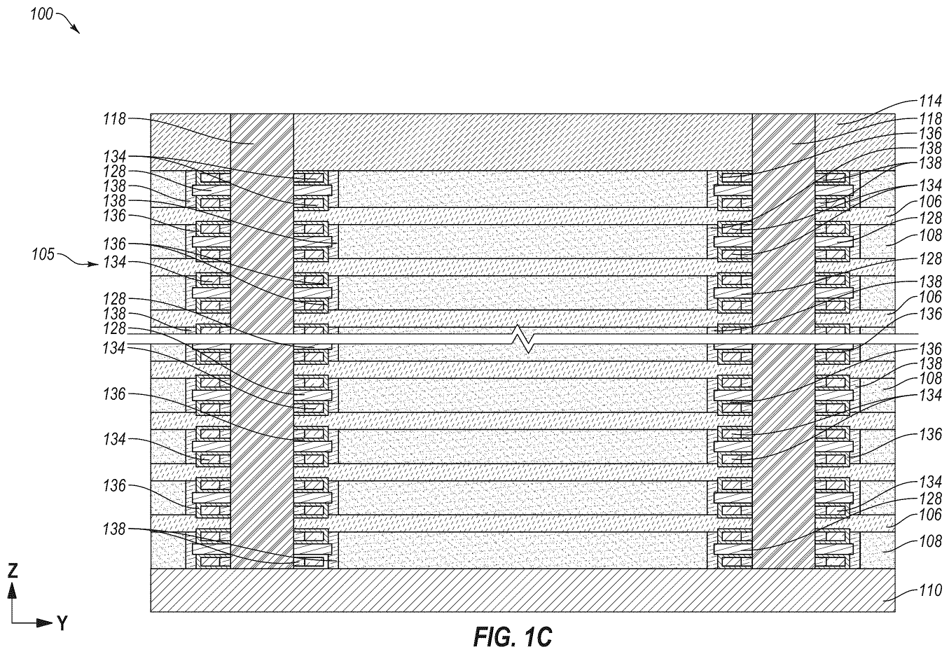

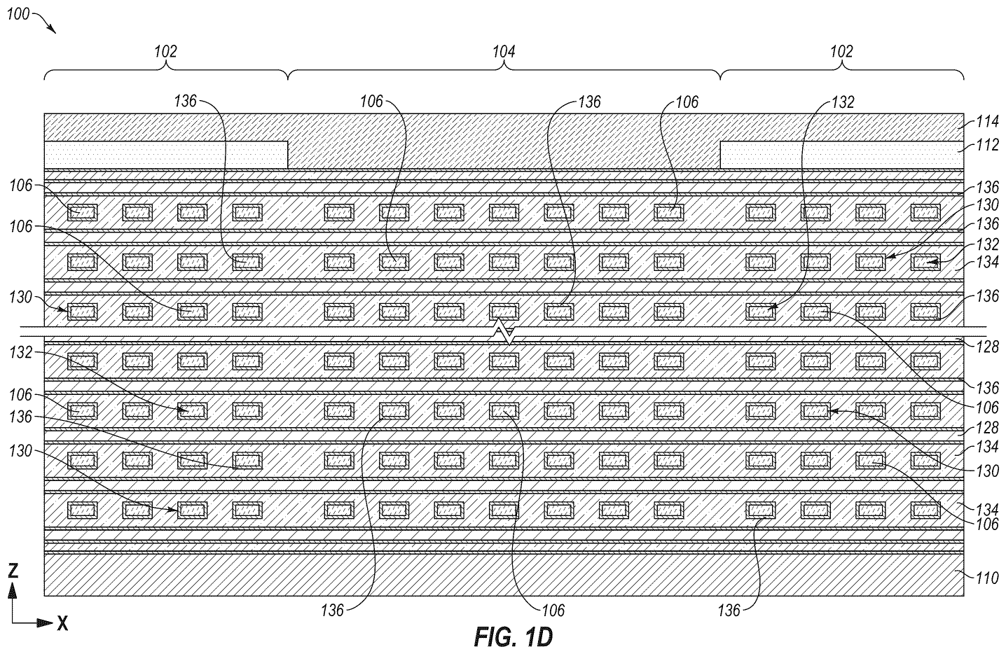

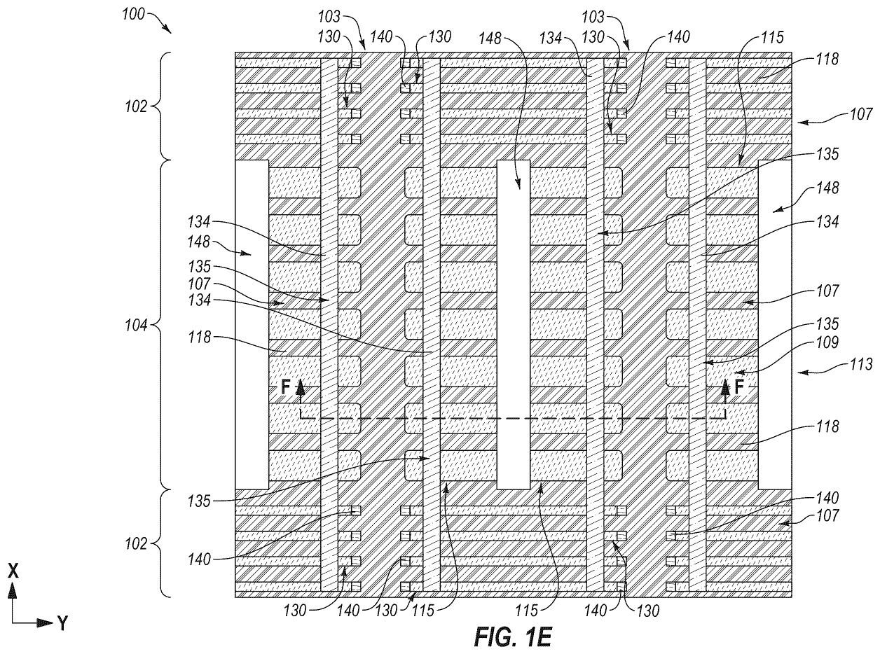

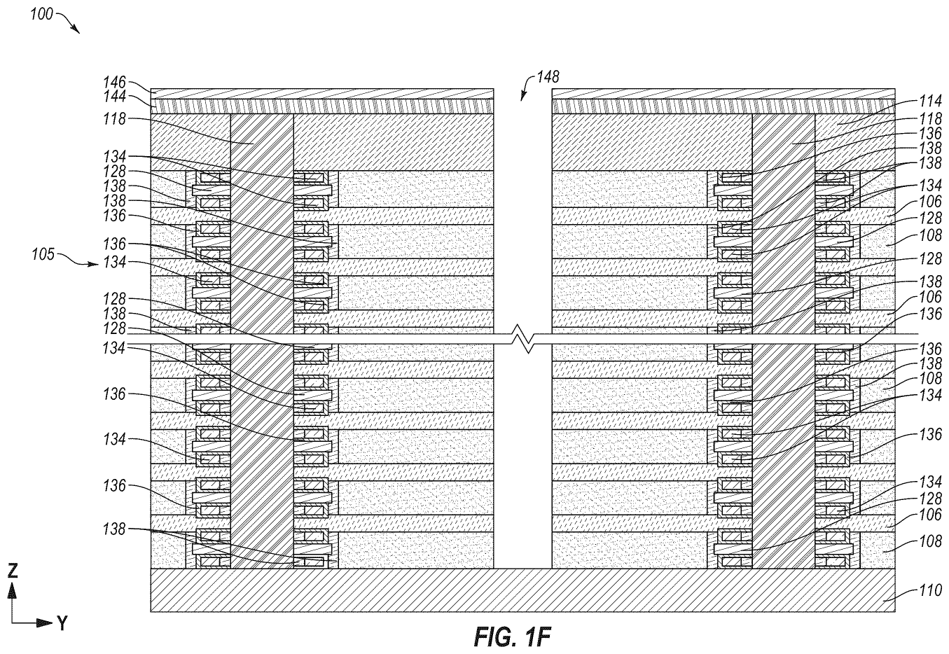

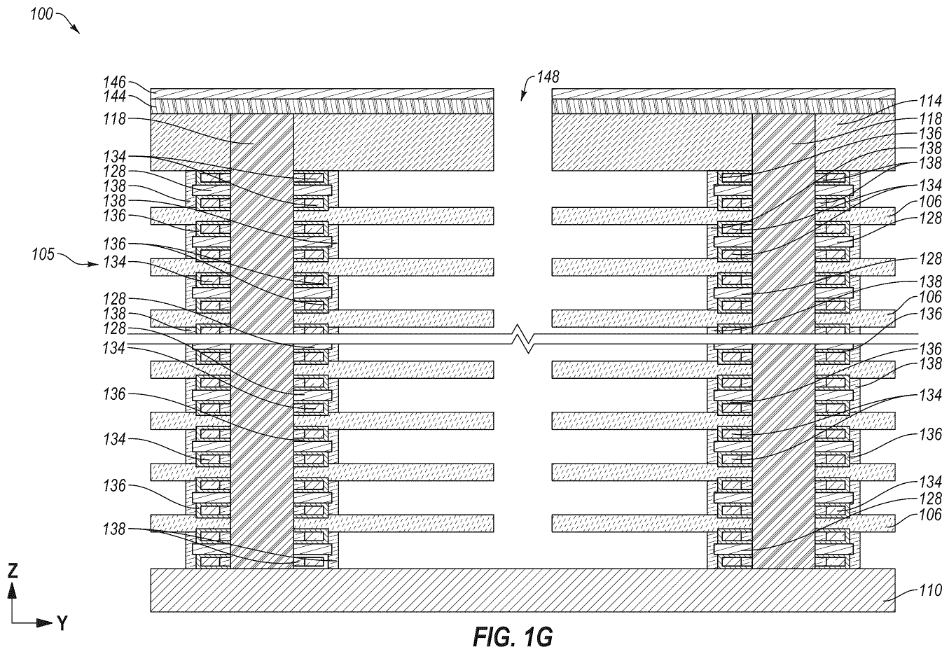

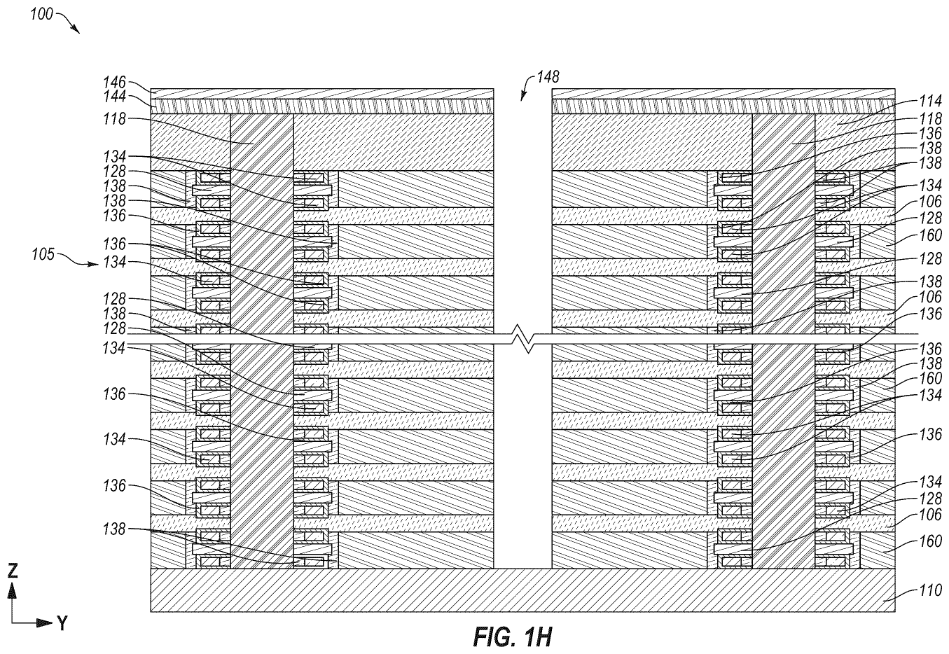

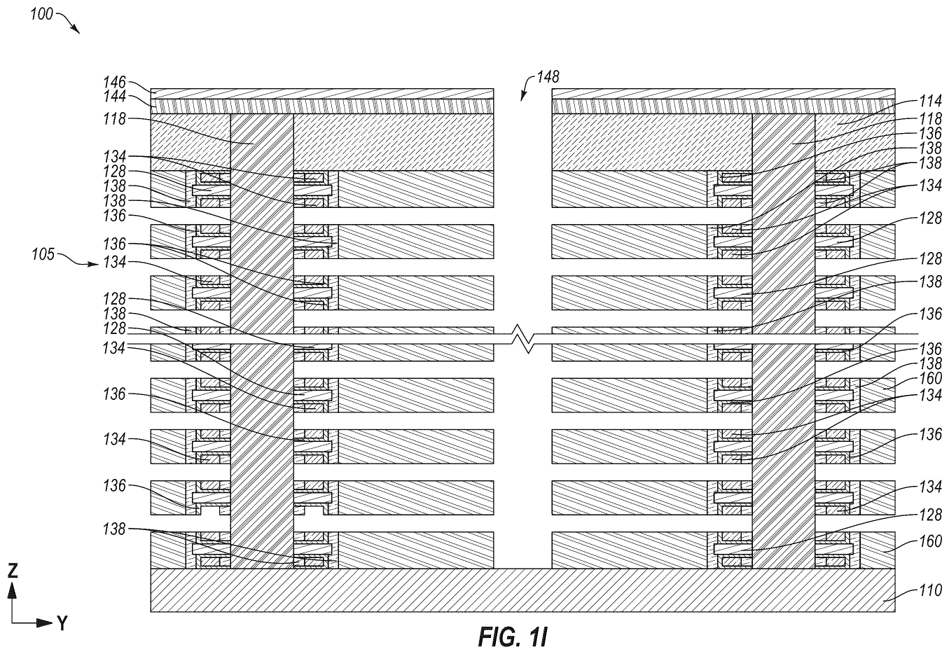

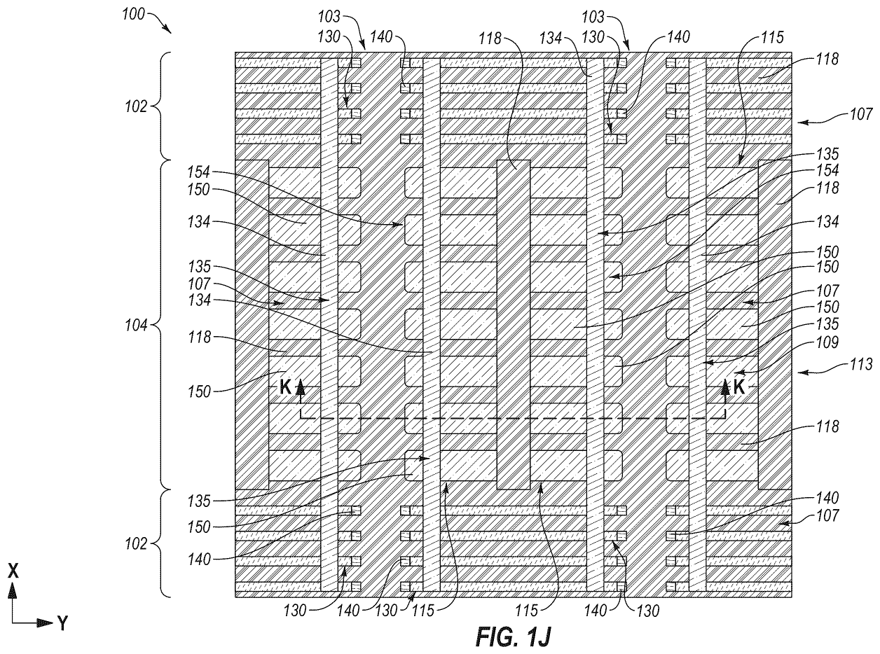

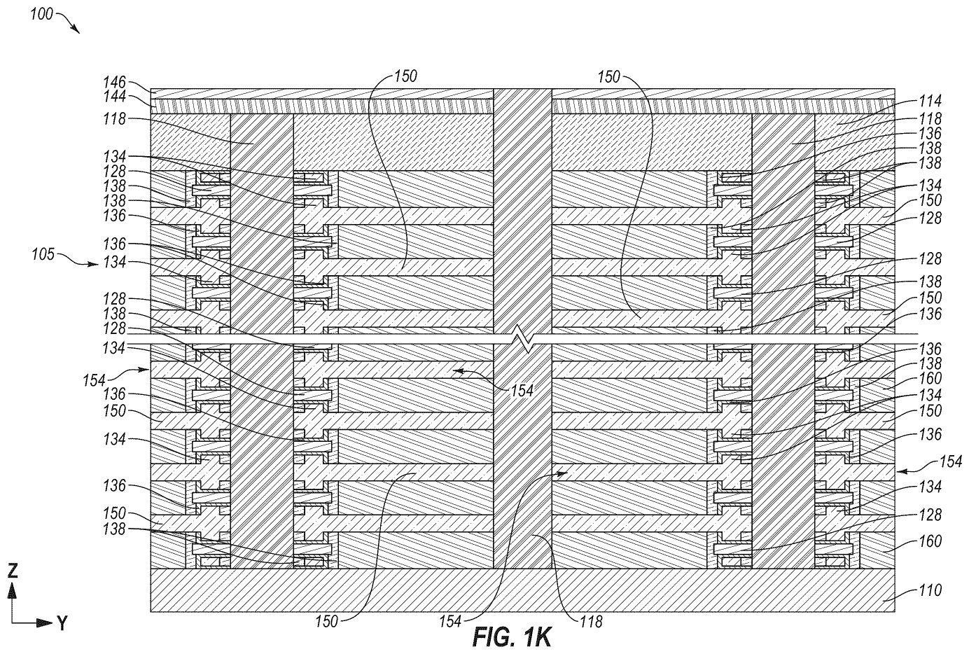

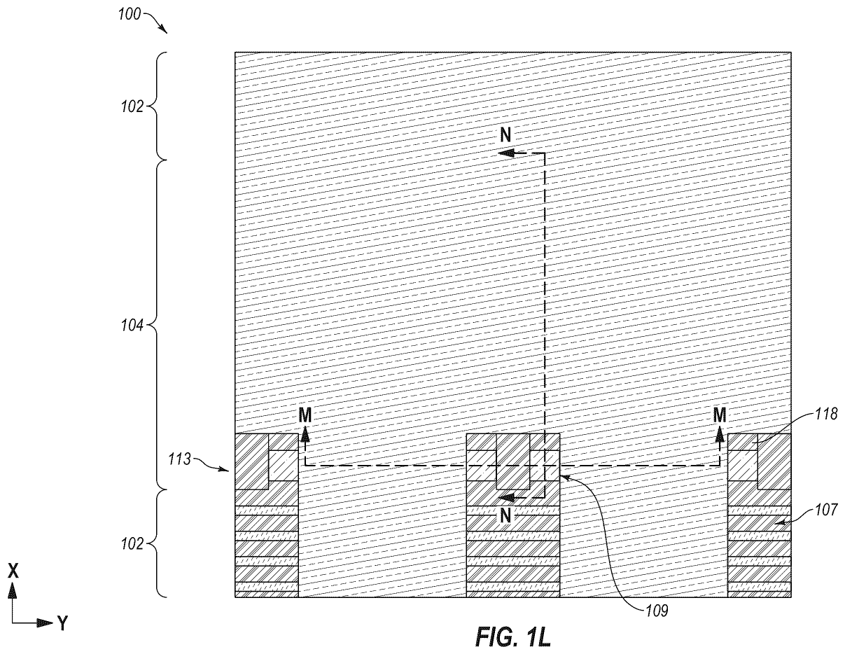

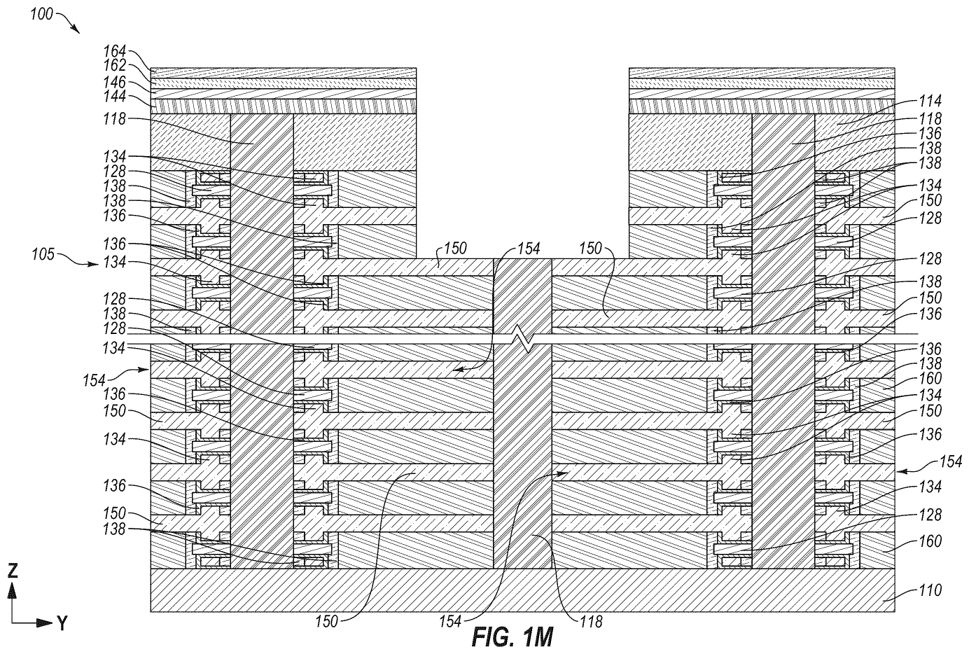

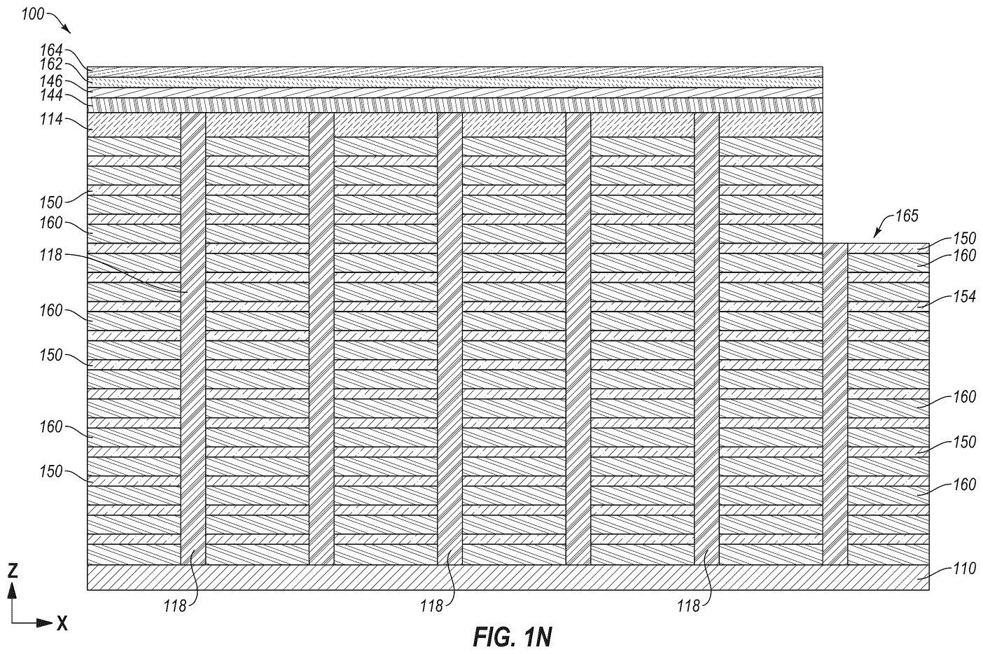

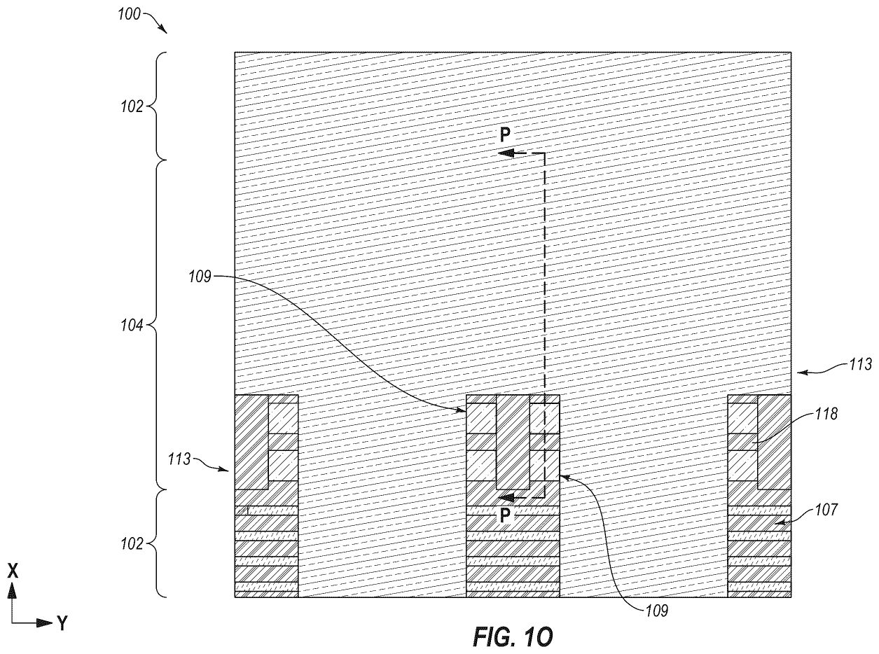

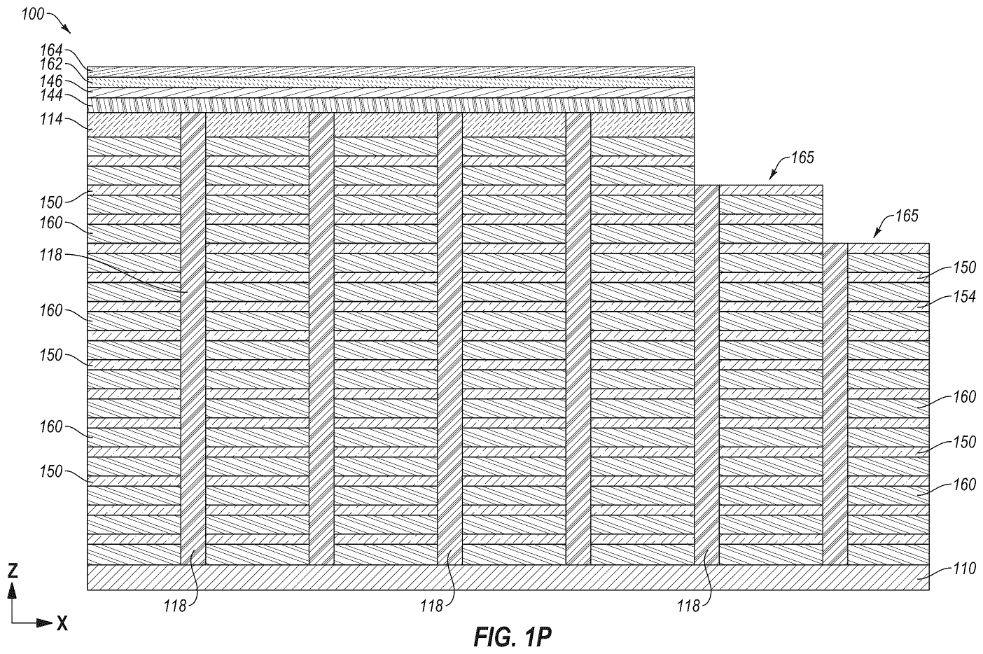

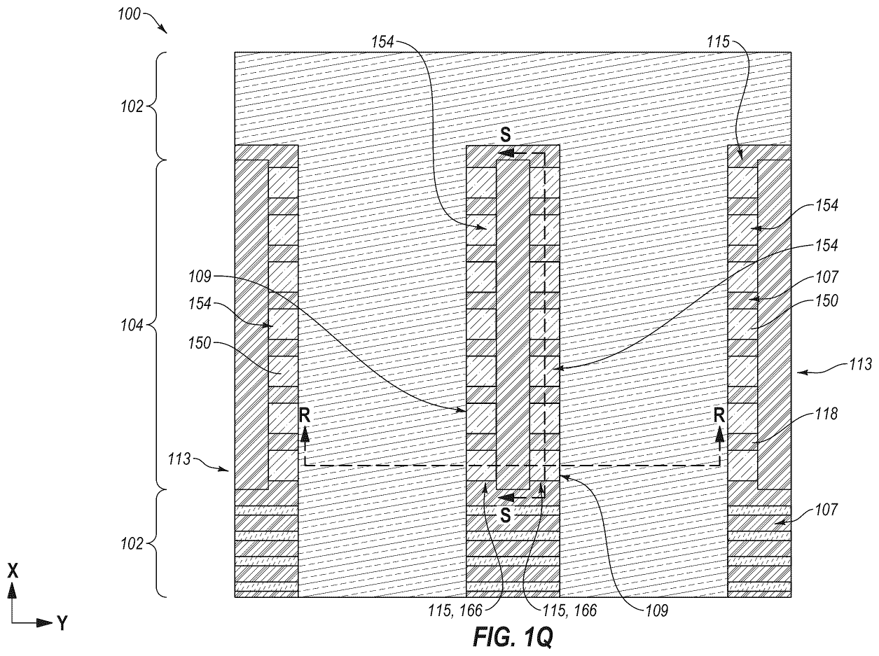

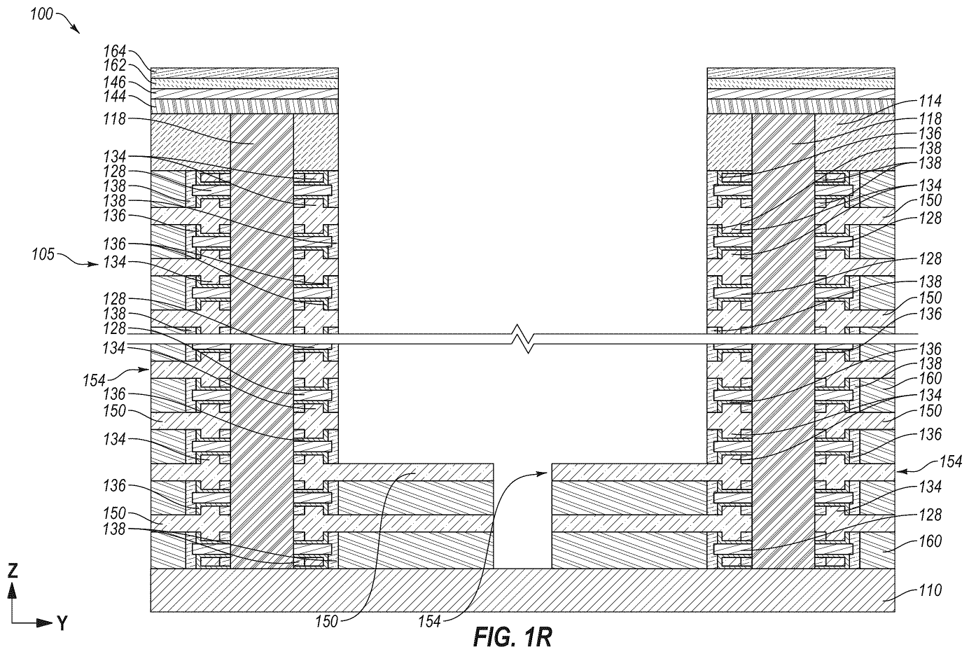

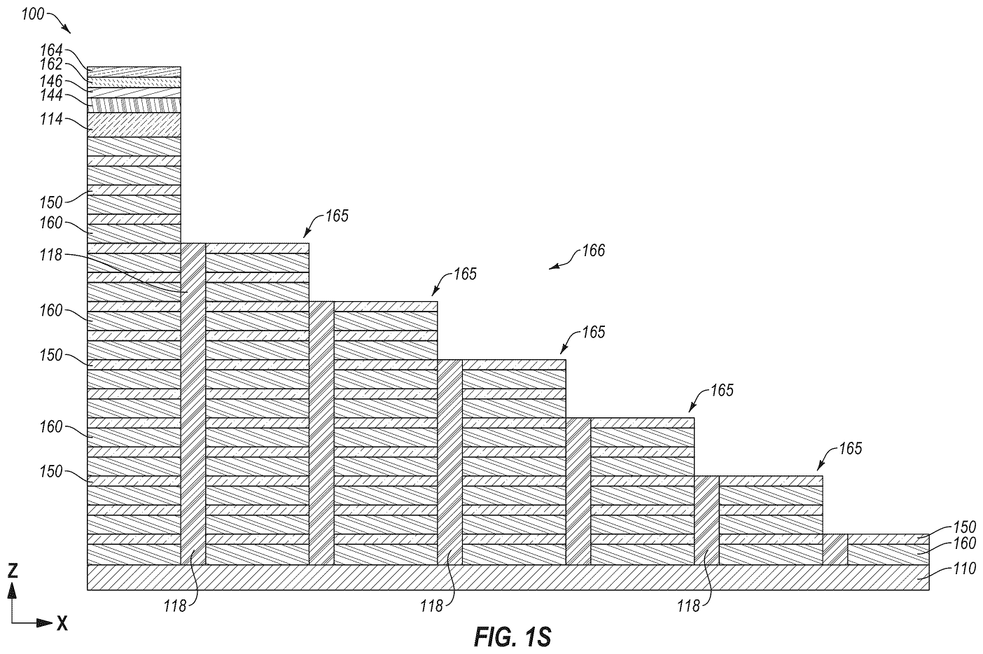

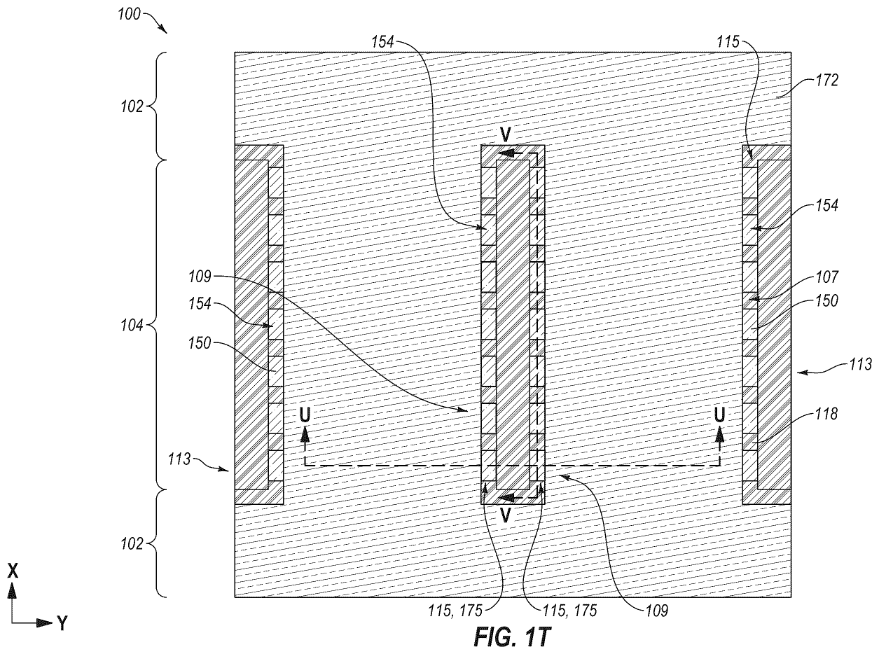

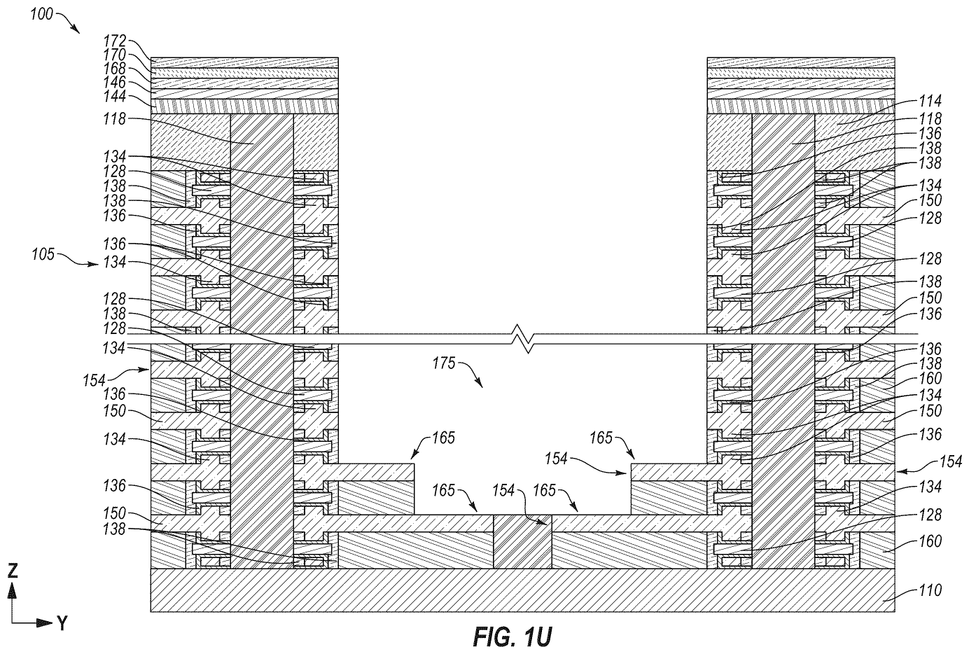

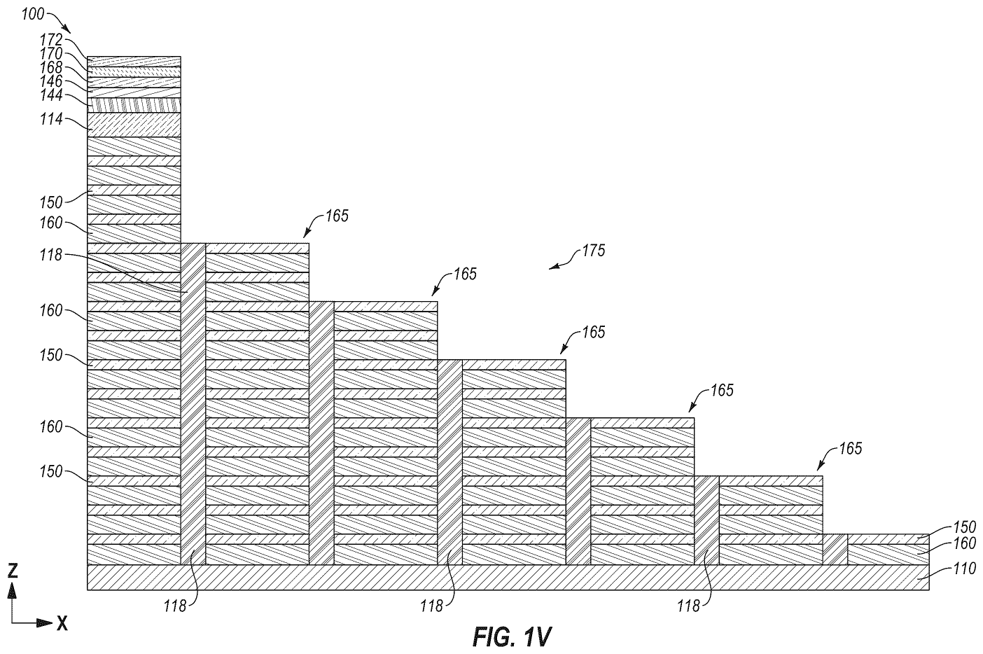

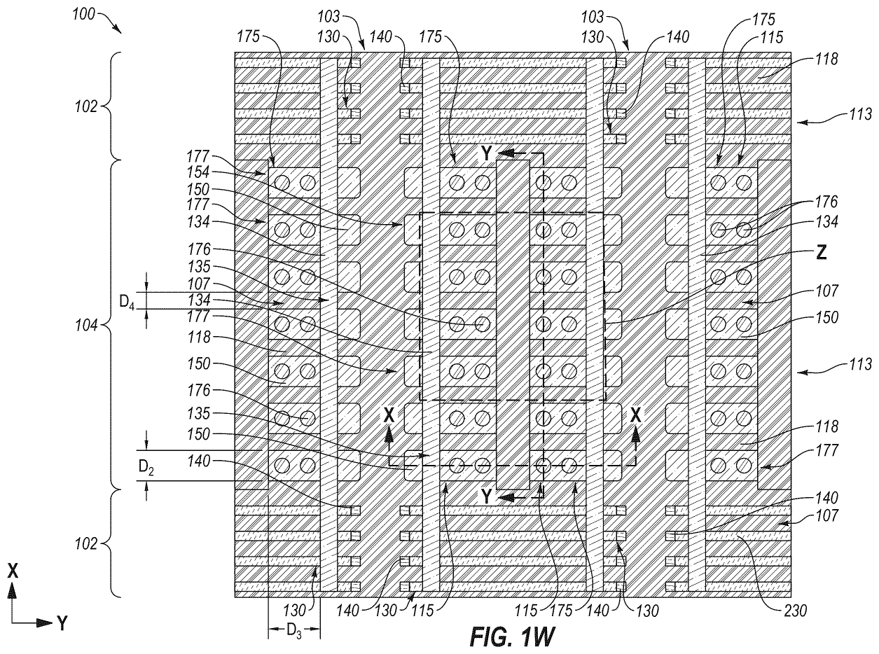

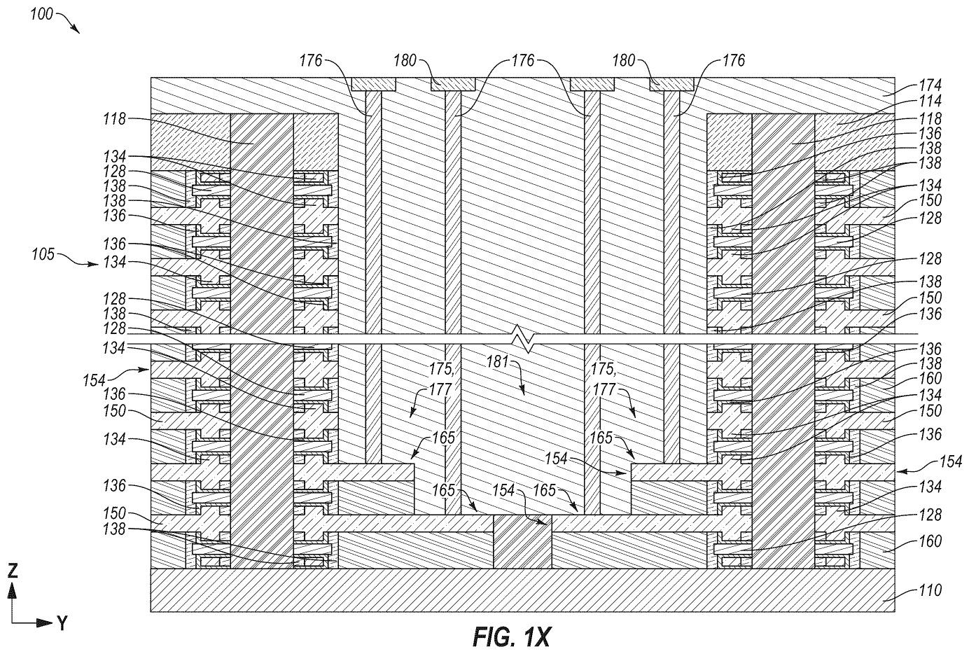

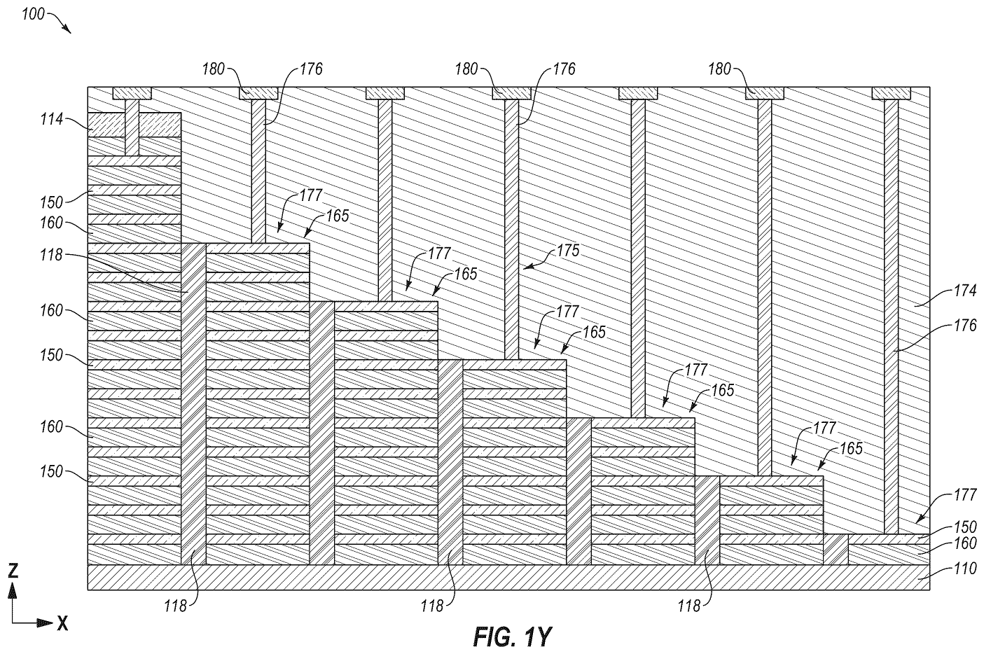

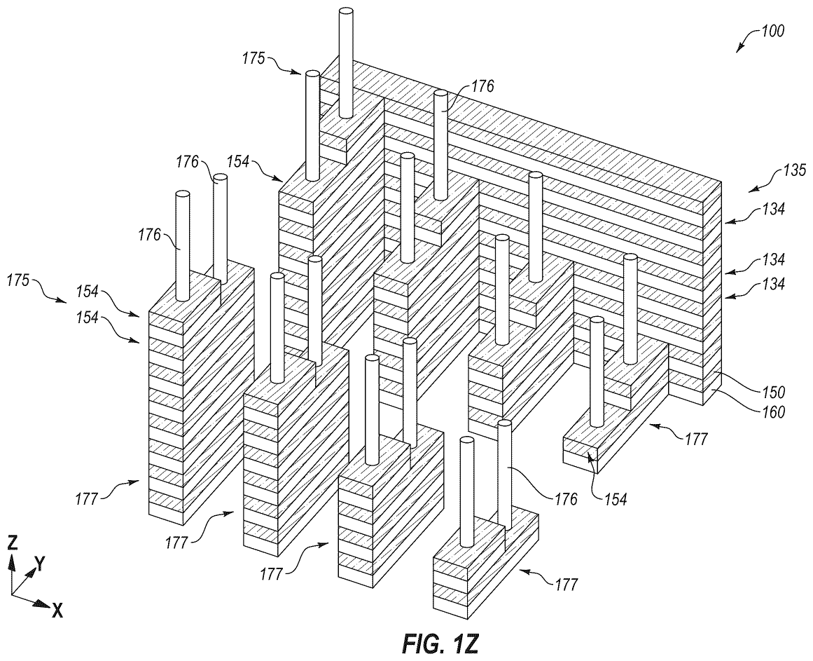

FIG. 1A through FIG. 1Z are simplified partial top-down views (FIG. 1A, FIG. 1E, FIG. 1J, FIG. 1L, FIG. 1O, FIG. 1Q, FIG. 1T, and FIG. 1W), simplified partial cross-sectional views (FIG. 1B through FIG. 1D, FIG. 1F through FIG. 1I, FIG. 1K, FIG. 1M, FIG. 1N, FIG. 1P, FIG. 1R, FIG. 1S, FIG. 1U, FIG. 1V, FIG. 1X, and FIG. 1Y), and a simplified partial perspective view (FIG. 1Z) illustrating a method of forming a first microelectronic device structure 100 (e.g., a memory device, such as a 3D DRAM memory device), in accordance with embodiments of the disclosure. With the description provided below, it will be readily apparent to one of ordinary skill in the art that the methods and structures described herein with reference to FIG. 1A through FIG. 1Z may be used in various devices and electronic systems. The first microelectronic device structure 100 may also be referred to herein as a first die or a first wafer.

FIG. 1A through FIG. 1D are a simplified partial top-down view (FIG. 1A) and simplified partial views (FIG. 1B through FIG. 1D) of a first microelectronic device structure 100 (e.g., a memory device, such as a 3D DRAM memory device), in accordance with embodiments of the disclosure. FIG. 1A is a simplified partial top-down view of the first microelectronic device structure 100; FIG. 1B is a simplified partial cross-sectional view of the first microelectronic device structure 100 taken through section line B-B of FIG. 1A; FIG. 1C is a simplified partial cross-sectional view of the first microelectronic device structure 100 taken through section line C-C of FIG. 1A; and FIG. 1D is a simplified partial cross-sectional view of the first microelectronic device structure 100 taken through section line D-D of FIG. 1A.

For clarity and ease of understanding the description, FIG. 1A does not illustrate some portions of the first microelectronic device structure 100 located on an uppermost surface of the first microelectronic device structure 100 to more clearly illustrate the relative location of portions of the first microelectronic device structure 100 located vertically underneath (e.g., in the Z-direction) the vertically uppermost surface of the first microelectronic device structure 100. For example, portions of a first material 106 are illustrated in FIG. 1A, even though the first material 106 is located vertically underneath (e.g., in the Z-direction) the vertically uppermost surface of the first microelectronic device structure 100, as described and illustrated with reference to FIG. 1B through FIG. 1D. Accordingly, the top-down views (FIG. 1A, FIG. 1E, FIG. 1G, FIG. 1I, FIG. 1L, FIG. 1O, FIG. 1Q, FIG. 1T, and FIG. 1W) of the first microelectronic device structure 100 do not illustrated the relative vertical position (e.g., in the Z-direction) of components of the first microelectronic device structure 100 with respect to one another; rather, the top-down views illustrated the relative horizontal positions (e.g., in the X-direction, in the Y-direction) of the illustrated components of the first microelectronic device structure 100 with respect to one another; and the relative vertical position of the components of the first microelectronic device structure 100 are illustrated in the cross-sectional views (FIG. 1B through FIG. 1D, FIG. 1F, FIG. 1H, FIG. 1J, FIG. 1K, FIG. 1M, FIG. 1N, FIG. 1P, FIG. 1R, FIG. 1S, FIG. 1U, FIG. 1V, FIG. 1X, and FIG. 1Y) illustrated herein.

Referring to FIG. 1A, the first microelectronic device structure 100 includes an array region 102 (also referred to herein as a “memory array region”) horizontally neighboring (e.g., in the X-direction) a staircase region 104 (also referred to herein as a “peripheral region”). In some embodiments, the staircase region 104 is horizontally interposed between (e.g., in the X-direction) array regions 102. In some embodiments, a horizontal area (e.g., in the XY plane) of the staircase region 104 is larger than a horizontal area of the individual array regions 102. In some embodiments, the horizontal area of the staircase region 104 is greater than the total horizontal area of the array regions 102 directly horizontally neighboring (e.g., in the X-direction) the staircase region 104.

Although FIG. 1A illustrates only one staircase region 104 and two array regions 102, the disclosure is not so limited. The first microelectronic device structure 100 may include more than one staircase region 104 and more than two array regions 102. In some embodiments, each staircase region 104 is horizontally interposed (e.g., in the X-direction) between two array regions 102. In some embodiments, horizontally neighboring staircase regions 104 are spaced from one another (e.g., in the X-direction) by two array regions 102 (e.g., a first array region 102 in operable communication with a first staircase structure of a first staircase region 104 and a second array region 102 in operable communication with a second staircase structure of a second staircase region 104). In some embodiments, the array regions 102 may each individually horizontally neighbor (e.g., in the X-direction) a staircase regions 104 and an additional array region 102. In other embodiments, the horizontal area of the staircase region 104 is less than the horizontal area of the array regions 102.

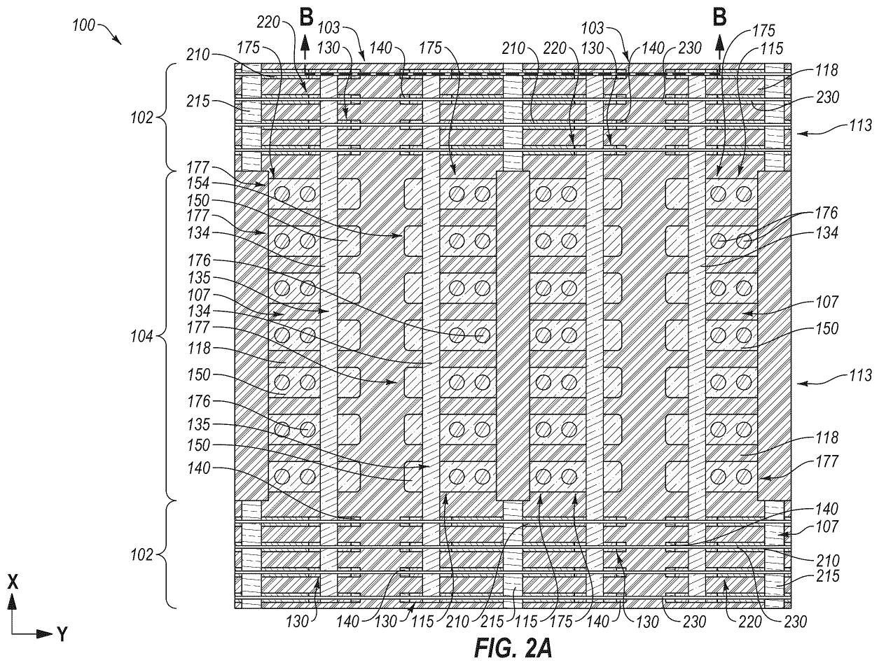

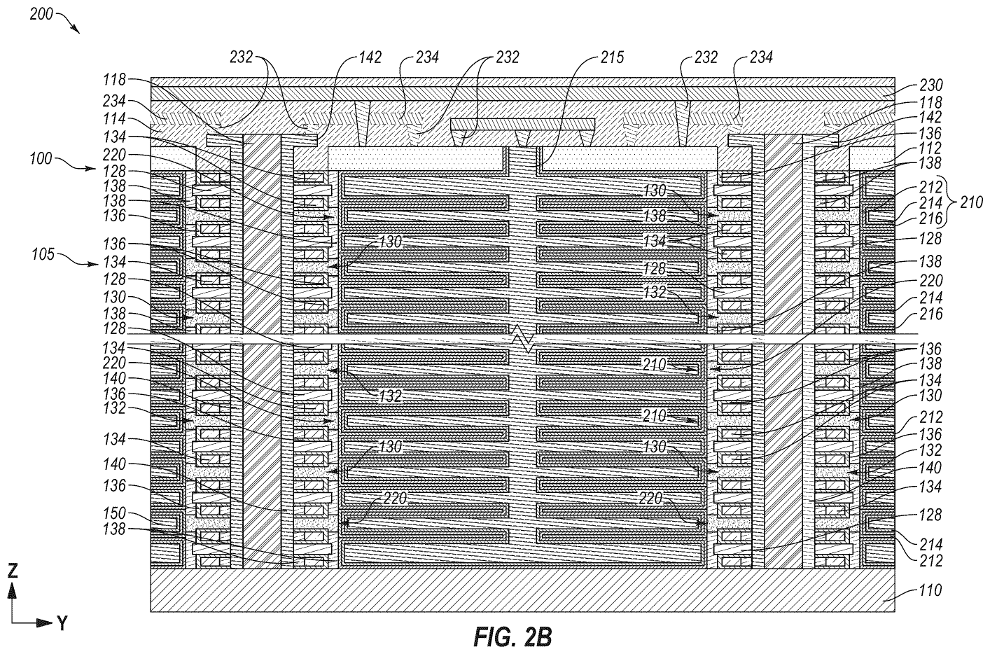

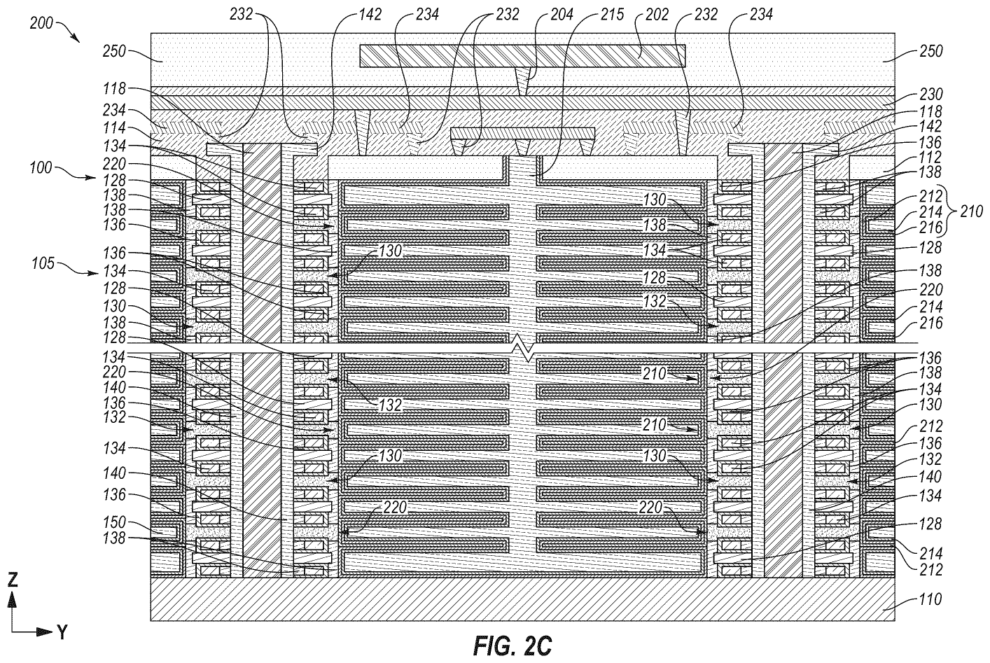

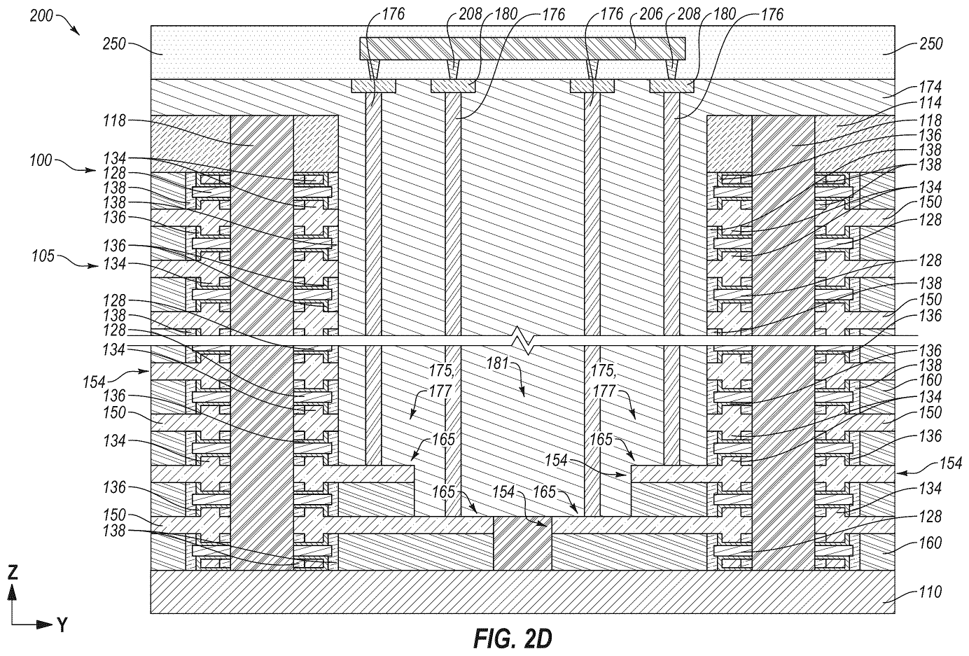

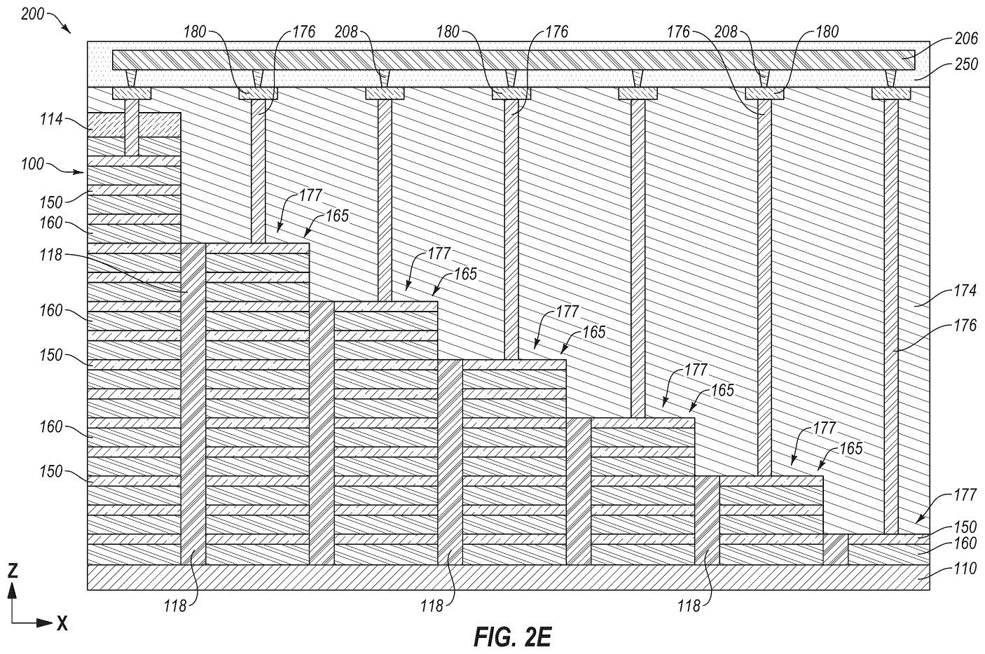

With reference to FIG. 1A through FIG. 1C, the first microelectronic device structure 100 includes a vertical stack structure 105 (also referred to as a “stack structure”) over a first base structure 110 from which a vertical stack of memory cells (e.g., vertical stack of memory cells 220 (FIG. 2A, FIG. 2B)) will be formed. The stack structure 105 includes a vertically alternating (e.g., in the Z-direction) sequence of a first material 106 and a second material 108.

The first base structure 110 may include a conventional silicon substrate (e.g., a conventional silicon wafer), or another bulk substrate comprising a semiconductive material. As used herein, the term “bulk substrate” means and includes not only silicon substrates, but also silicon-on-insulator (SOI) substrates, such as silicon-on-sapphire (SOS) substrates and silicon-on-glass (SOG) substrates, epitaxial layers of silicon on a base semiconductive foundation, and other substrates formed of and including one or more semiconductive materials (e.g., one or more of a silicon material, such as monocrystalline silicon or polycrystalline silicon; silicon-germanium; germanium; gallium arsenide; gallium nitride; and indium phosphide). In some embodiments, the first base structure 110 comprises a silicon wafer.

With reference to FIG. 1A, in some embodiments, each of the array regions 102 and the staircase region 104 includes first isolation regions 103 horizontally extending (e.g., in the X-direction) through the array regions 102 and the staircase region 104. Within the array regions 102, the first isolation regions 103 may horizontally separate (e.g., in the Y-direction) horizontally neighboring (e.g., in the Y-direction) active regions (e.g., access devices 130); and within the staircase region 104, the first isolation regions 103 may horizontally separate (e.g., in the Y-direction) horizontally neighboring active regions (e.g., horizontally neighboring first materials 106). The first isolation regions 103 may vertically extend (e.g., in the Z-direction) through the stack structure (FIG. 1B) and terminate at, for example, the first base structure 110.

With continued reference to FIG. 1A, second isolation regions 107 may horizontally extend (e.g., in the Y-direction) through the array regions 102 and the staircase region 104. Within the array regions 102, the second isolation regions 107 may horizontally separate (e.g., in the X-direction) horizontally neighboring (e.g., in the X-direction) active regions (e.g., the access devices 130); and within the staircase region 104, the second isolation regions 107 may horizontally separate (e.g., in the Y-direction) horizontally neighboring active regions (e.g., horizontally neighboring first materials 106).

In some embodiments, the second isolation regions 107 may be formed within the array regions 102 and the staircase regions 104 substantially concurrently. In some embodiments, a horizontal dimension D₁ (e.g., in the X-direction) of the second isolation regions 107 in the array regions 102 may be substantially the same as the dimension D₁ of the second isolation regions 107 in the staircase region 104.

Within the staircase region 104, the first isolation regions 103 and the second isolation regions 107 may horizontally separate (e.g., in the Y-direction) horizontally neighboring (e.g., in the X-direction, in the Y-direction) portions of the first material 106 into isolated structures 109, each comprising portions of the first material 106. The isolated structures 109 may be separated into rows 115 of the isolated structures 109 horizontally separated (e.g., in the Y-direction) from one another by the first isolation regions 103 and columns 113 of the isolated structures 109 horizontally separated (e.g., in the X-direction) from one another by the second isolation regions 107.

Each of the first isolation regions 103 and the second isolation regions 107 may individually be formed of and include a first insulative material 118. The first insulative material 118 may be formed of and include insulative material. In some embodiments, the first insulative material 118 is formed of and includes insulative material, such as one or more of an oxide material (e.g., silicon dioxide (SiO₂), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), aluminum oxide (Al₂O₃), or a combination thereof), and amorphous carbon. In some embodiments, the first insulative material 118 comprises silicon dioxide.

With reference to FIG. 1B and FIG. 1D, semiconductive material 112 vertically overlies (e.g., in the Z-direction) the stack structure 105 with the array regions 102 (FIG. 1A). In some embodiments, the semiconductive material 112 comprises silicon, such as single-crystal silicon. In some embodiments, the semiconductive material 112 comprises epitaxially-grown silicon. As described in further detail herein, the semiconductive material 112 may be used to form one or more control logic devices of the first microelectronic device structure 100 to facilitate control operations for memory cells (e.g., memory cells 220 (FIG. 2A, FIG. 2B)) of the first microelectronic device structure 100.

A second insulative material 114 vertically overlies (e.g., in the Z-direction) the semiconductive material 112 in the array regions 102 and the stack structure 105 within the staircase region 104. The second insulative material 114 may be formed of and include one or more of the materials described above with reference to the first insulative material 118. In some embodiments, the second insulative material 114 comprises substantially the same material composition as the first insulative material 118.

The first material 106 may be formed of and include, for example, a semiconductive material (e.g., silicon) or an oxide material (e.g., silicon dioxide). In some embodiments, the first material 106 comprises silicon, such as epitaxially grown silicon. In some embodiments, the first material 106 comprises monocrystalline silicon.

The second material 108 may have a different material composition than the first material 106 and may have etch selectivity with respect to the first material 106. The second material 108 may be formed of and include one or more of silicon germanium, polysilicon, a nitride material (e.g., silicon nitride (Si₃N₄)), or an oxynitride material (e.g., silicon oxynitride). In some embodiments, such as where the first material 106 comprises silicon, the second material 108 comprises silicon germanium, such as epitaxially grown silicon germanium. In other embodiments, such as where the first material 106 comprises silicon, the second material 108 comprises polysilicon. In yet other embodiments, such as where the first material 106 comprises silicon dioxide, the second material 108 comprises silicon nitride or silicon oxynitride.

With reference to FIG. 1A, FIG. 1B, and FIG. 1C, a vertical stack of access devices 130 may be formed vertically extending (e.g., in the Z-direction) through the stack structure 105. The vertical stack of access devices 130 may include vertically spaced (e.g., in the Z-direction) access devices 130, each formed within a level of the first material 106.

Within the array regions 102, the access devices 130 may comprise doped portions of the first material 106 to form channel regions 132 (FIG. 1B, FIG. 1D). The channel regions 132 may be doped with one or more of at least one N-type dopant, such as one or more of arsenic ions, phosphorous ions, and antimony ions. In other embodiments, the channel regions 132 are doped with at least one P-type dopant, such as one or more of boron ions, aluminum ions, and gallium ions. In some embodiments, the channel regions 132 of the access devices 130 are positioned horizontally between (e.g., in the X-direction, in the Y-direction) a source region and a drain region of the access devices 130. The access devices 130 vertically overlying (e.g., in the Z-direction) one another may be form a vertical stack of access devices 130.

Within the staircase region 104, the first material 106 may not include access devices 130 (FIG. 1A, FIG. 1B, FIG. 1D). As described in further detail herein, within the staircase region 104, the first material 106 may be selectively removed with respect to the second material 108 and replaced with a conductive material to form portions (e.g., second conductive structures 154 (FIG. 1I, FIG. 1J)) of staircase structures (e.g., staircase structures 175 (FIG. 1W through FIG. 1Z)).

Referring to FIG. 1B through FIG. 1D, in some embodiments, first conductive structures 134 vertically overlie (e.g., in the Z-direction) and vertically underlie (e.g., in the Z-direction) each of the access devices 130. By way of non-limiting example, the first conductive structures 134 may vertically overlie and vertically underlie the channel regions 132 of each of the access devices 130. In some embodiments, the channel regions 132 are vertically surrounded by the first conductive structures 134. In some embodiments, vertically neighboring (e.g., in the Z-direction) first conductive structures 134 between vertically neighboring (e.g., in the Z-direction) access devices 130 are spaced from each other by a third insulative material 128 (FIG. 1B).

The first conductive structures 134 may individually be formed of and include conductive material, such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium, etc.), polysilicon, or other materials exhibiting electrical conductivity.

The first conductive structures 134 may horizontally extend (e.g., in the X-direction) as lines and may extend from one array region 102, through the staircase region 104, and to another array region 102. The first conductive structures 134 horizontally extend (e.g., in the X-direction) substantially continuously through the staircase region 104 horizontally intervening (e.g., in the X-direction) between two array regions 102. As described in further detail herein, the first conductive structures 134 may individually be referred to herein as “first conductive lines,” “access lines,” or “word lines.”

In some embodiments, the first conductive structures 134 form a vertical stack structure 135. The vertical stack structure 135 horizontally extends (e.g., in the X-direction) substantially continuously through the staircase region 104 horizontally intervening (e.g., in the X-direction) between two array regions 102. The vertical stack structure 135 comprises levels of the first conductive structures 134 vertically (e.g., in the Z-direction) spaced from one another. In some embodiments, the vertical stack structure 135 horizontally terminates (e.g., in the X-direction) within the horizontal boundaries (e.g., in the X-direction) of the array regions 102 (e.g., at the horizontal boundaries (e.g., in the X-direction) of the array regions 102). In some embodiments, the vertical stack structure 135 does not horizontally extend (e.g., in the X-direction) beyond a horizontal boundary of the array regions 102 on a horizontal side of the respective array region 102 opposite the staircase region 104.

The third insulative material 128 may be formed of and include an insulative material that is different than, and that has etch selectivity with respect to, the first material 106. In some embodiments, the third insulative material 128 is formed of and includes one or more of the materials described above with reference to the first insulative material 118. In some embodiments, the third insulative material 128 is formed of and include an oxide material (e.g., silicon dioxide).

With continued reference to FIG. 1B and FIG. 1D, each of the access devices 130 (FIG. 1B, FIG. 1D) is at least partially surrounded by a dielectric material 136, which may also be referred to herein as a “gate dielectric material.” With reference to FIG. 1C, the first material 106 in the staircase region 104 is at least partially surrounded by the dielectric material 136. In some embodiments, the portion of the first conductive structure 134 directly vertically neighboring (e.g., in the Z-direction) and located within horizontal boundaries (e.g., in the X-direction, in the Y-direction) of the dielectric material 136 may be referred to as a “gate electrode.” In some embodiments, the first conductive structures 134 are separated from the access devices 130 by the dielectric material 136.

The dielectric material 136 may be formed of and include insulative material. By way of non-limiting example, the dielectric material 136 may comprise one or more of phosphosilicate glass, borosilicate glass, borophosphosilicate glass (BPSG), fluorosilicate glass, silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material, (e.g., silicon nitride (Si₃N₄)), an oxynitride (e.g., silicon oxynitride), another gate dielectric material, a dielectric carbon nitride material (e.g., silicon carbon nitride (SiCN)), or a dielectric carboxynitride material (e.g., silicon carboxynitride (SiOCN)).

With reference to FIG. 1D, each of the access devices 130 is substantially surrounded by the dielectric material 136 that is substantially surrounded by the first conductive structure 134. In some such embodiments, the access devices 130 individually comprise so-called “gate all around” access devices (e.g., gate all around transistors) since each of the access devices 130 is individually substantially surrounded by one of the conductive structures 134.

Vertically neighboring (e.g., in the Z-direction) access devices 130 and levels of the first material 106 are spaced from one another by a fourth insulative material 138 (FIG. 1B, FIG. 1C). In some embodiments, the fourth insulative material 138 surrounds at least a portion of the dielectric material 136 and horizontally intervenes (e.g., in the Y-direction) between the dielectric material 136 and the second material 108.

The fourth insulative material 138 may be formed of and include insulative material having etch selectivity with respect to the second material 108. In some embodiments, the fourth insulative material 138 comprises a nitride material (e.g., silicon nitride (Si₃N₄)) or an oxynitride material (e.g., silicon oxynitride). In some embodiments, the fourth insulative material 138 comprises silicon nitride.

With reference to FIG. 1A and FIG. 1B, conductive pillar structures 140 may vertically extend (e.g., in the Z-direction) through the first microelectronic device structure 100 and horizontally neighbor (e.g., in the Y-direction) and contact the channel regions 132 of the access devices 130. The conductive pillar structures 140 may also be referred to herein as “digit lines,” “second conductive lines,” “digit line pillar structures,” “local digit lines,” or “vertical digit lines.” Each conductive pillar structure 140 vertically extends through the first microelectronic device structure 100, such as through or horizontally neighboring (e.g., in the Y-direction) the vertical stack of access devices 130. In some embodiments, the conductive pillar structures 140 horizontally neighbor (e.g., in the Y-direction) a source region or a drain region of the access devices 130. In other embodiments, such as where the access devices 130 consist essentially of the channel regions 132 (and do not include, for example, a source region and a drain region), the conductive pillar structures 140 directly contact the channel region 132 of the access devices 130. The conductive pillar structures 140 are individually in contact with the access devices 130 of the vertical stack of access devices 130.

The conductive pillar structures 140 may individually be formed of and include conductive material, such as one or more of the materials described above with reference to the first conductive structures 134.

With reference to FIG. 1A, in some embodiments, the staircase region 104 does not include any of the conductive pillar structures 140 within a horizontal area thereof.

With continued reference to FIG. 1B, the conductive pillar structures 140 may individually be in contact with conductive material 142 horizontally extending (e.g., in the Y-direction) from the conductive pillar structure 140 and vertically over (e.g., in the Z-direction) the second insulative material 114. For clarity and ease of understanding the description, the conductive material 142 is not illustrated in FIG. 1A.

The conductive material 142 may be formed of and include one or more of the materials described above with reference to the conductive pillar structures 140.

In some embodiments, the first material 106 within the array regions 102 and the staircase region 104 may be patterned (e.g., to form the access devices 130 in the array regions 102 and pattern the first material 106 in the staircase region 104) substantially concurrently. By way of non-limiting example, trenches may be formed at locations corresponding to the first isolation regions 103 (FIG. 1A through FIG. 1C). Portions of each of the levels of the second material 108 may be selectively removed through the trenches to form recesses within the second material 108 at each of the levels. Portions of the first insulative material 118 of the second isolation regions 107 may be selectively removed (e.g., in the Y-direction) with respect to the first material 106 and the second material 108 through the trenches. After removing portions of the first insulative material 118 through the trenches, portions of the second material 108 may be selectively removed in the horizontal direction (e.g., in the Y-direction) relative to the first material 106 to form recesses in the levels of the second material 108 and form levels of the first material 106 horizontally extending (e.g., in the Y-direction) closer to the trenches than levels of the second material 108.

After removing the portions of the levels of the second material 108 through the trenches, the fourth insulative material 138 may be formed over surfaces of the first material 106 and the vertically extending (e.g., in the Z-direction) surfaces of the second material 108 within the recesses. The fourth insulative material 138 may be formed as, for example, a liner material (e.g., does not substantially fill the recesses). After forming the fourth insulative material 138, the third insulative material 128 may be formed over surfaces of the fourth insulative material 138 and within remaining portions of the recesses and the trenches.

After forming the fourth insulative material 138 and the third insulative material 128, portions of the third insulative material 128 may be removed (e.g., vertical portions of the third insulative material 128 may be removed) to expose sidewalls of fourth insulative material 138. In some embodiments, the exposed portions of the fourth insulative material 138 are selectively removed (e.g., in the Y-direction) to recess the fourth insulative material 138 relative to the third insulative material 128 and expose portions of the levels of the first material 106. Exposed portions of the first material 106 may selectively be removed to vertically thin (e.g., in the Z-direction) the exposed portions of the first material 106. After vertically thinning the exposed portions of the first material 106, the dielectric material 136 is formed on surfaces of the first material 106, surfaces of the fourth insulative material 138, and surfaces of the third insulative material 128.

A conductive material may be formed over surfaces of the dielectric material 136 to form the first conductive structures 134. In some embodiments, the conductive material is formed by one or more of ALD, CVD, and PVD. After forming the conductive material, portions of the conductive material may selectively be removed (e.g., in the Y-direction) with respect to, for example, the dielectric material 136, to form the first conductive structures 134 horizontally extending (e.g., in the X-direction) as lines through the array regions 102 and the staircase regions 104, each first conductive structure 134 horizontally extending as a continuous integral structure.

After forming the first conductive structures 134, additional portions of the fourth insulative material 138 may be formed to form the access devices 130. The additional portions of the fourth insulative material 138 may be formed to horizontally neighbor (e.g., in the Y-direction) the first conductive structures 134 and may be formed on surfaces of the dielectric material 136. After forming the access devices 130, the conductive pillar structures 140 (FIG. 1A, FIG. 1B) and the conductive material 142 (FIG. 1A, FIG. 1B) may be formed within the array regions 102. The conductive pillar structures 140 (FIG. 1A, FIG. 1B) and the conductive material 142 (FIG. 1A, FIG. 1B) may not be formed within (e.g., may be omitted from) the staircase region 104. In addition, the first isolation regions 103 may be filled with the first insulative material 118.

FIG. 1E and FIG. 1F are a simplified partial top-down view (FIG. 1E) and a simplified partial cross-sectional view (FIG. 1F) of the first microelectronic device structure 100 at a processing stage subsequent to that illustrated in FIG. 1A through FIG. 1D. FIG. 1F is a simplified cross-sectional view of the first microelectronic device structure 100 taken through section line F-F of FIG. 1E.

With collective reference to FIG. 1E and FIG. 1F, a first mask material 144 (FIG. 1F) and an oxide material 146 (FIG. 1F) may be formed over the first microelectronic device structure 100 over the array regions 102 and over portions of the staircase region 104. The first mask material 144 and the oxide material 146 are not illustrated in FIG. 1E for clarity and case of understanding the description. In some embodiments, substantially all of each of the array regions 102 is covered by the first mask material 144 and the oxide material 146 and a majority of the staircase region 104 is covered by the first mask material 144 and the oxide material 146. Within the staircase region 104, trenches 148 may be formed within the first mask material 144 and the oxide material 146. In some embodiments, the trenches 148 are horizontally between vertical stack structures 135 of conductive structures 134 that are horizontally between (e.g., in the Y-direction) two of the first isolation regions 103.

With reference to FIG. 1F, the trenches 148 may vertically extend (e.g., in the Z-direction) through the first mask material 144, the oxide material 146, the second insulative material 114, and the stack structure 105 (e.g., the vertically alternating sequence of the first material 106 and the second material 108). In some embodiments, the trenches 148 vertically extend (e.g., in the Z-direction) to the first base structure 110.

In some embodiments, the trenches 148 may horizontally separate (e.g., in the Y-direction) the isolated structures 109 of the first material 106 into rows 115 of the isolated structures 109. In some embodiments, the first microelectronic device structure 100 includes two rows 15 of the isolated structures 109 horizontally between (e.g., in the Y-direction) horizontally neighboring (e.g., in the Y-direction) first isolation regions 103.

The first mask material 144 may be formed of and include one or more of a photoresist material, nitride mask (e.g., silicon nitride, titanium nitride, aluminum nitride), silicon carbide, carbon doped hydrogenated silicon oxide (SiOCH), amorphous carbon, and a spin-on mask material. In some embodiments, the first mask material 144 comprises a hardmask material. However, the disclosure is not so limited and the first mask material 144 may include materials other than those described above.

The oxide material 146 may be formed of and include a material having a different material composition than the first mask material 144. The oxide material 146 may be formed of and include an oxide material (e.g., silicon dioxide (SiO₂), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), aluminum oxide (Al₂O₃), or a combination thereof), and amorphous carbon. In some embodiments, the oxide material 146 comprises silicon dioxide.

FIG. 1G is a simplified partial cross-sectional view of the microelectronic device structure 100 at a processing stage subsequent to that illustrated in FIG. 1F. With reference to FIG. 1G, portions of the second material 108 (FIG. 1F) within the staircase region 104 may selectively be removed (e.g., relative to the second material 108 and the fourth insulative material 138) through the trenches 148. Removal of the second material 108 may expose portions of the first material 106 and portions of the fourth insulative material 138. In some embodiments, removal of the second material 108 may remove substantially all of the second material 108 from within the staircase region 104 and expose portions of the fourth insulative material 138.

In some embodiments, the second material 108 (FIG. 1F) is removed selective to the first material 106, the second insulative material 114, the first conductive structures 134, the dielectric material 136, the first mask material 144, and the oxide material 146 by exposing the second material 108 to one or both of a dry etch process and a wet etch process. By way of non-limiting example, the second material 108 may be removed selective to the first material 106 by exposing the second material 108 to a dry etch including one or both of hydrogen fluoride (HF) and methanol (CH₃OH); followed by a plasma treatment with one or more of carbon tetrafluoride (CF₄), fluorine (F₂), ammonia (NH₃), argon, and chlorine trifluoride (ClF₃).

Referring next to FIG. 1H, after selectively removing the second material 108 (FIG. 1F) relative to the first material 106, a fifth insulative material 160 may be formed at locations corresponding to the locations of the second material 108 (FIG. 1F). The fifth insulative material 160 may be formed vertically between (e.g., in the Z-direction) vertically neighboring (e.g., in the Z-direction) levels of the first material 106.

After forming the fifth insulative material 160, portions of the fifth insulative material 160 may be removed from over surfaces of the microelectronic device structure 100 and from vertical sidewalls of the trenches 148 to expose sidewalls of the levels of the first material 106 at the trenches 148.

The fifth insulative material 160 may be formed of and include one or more of the materials described above with reference to the second insulative material 114. In some embodiments, the fifth insulative material 160 comprises substantially the same material composition as the second insulative material 114. In some embodiments, the fifth insulative material 160 comprises an oxide material. In some embodiments, the fifth insulative material 160 comprises silicon dioxide.

With reference to FIG. 1I, after forming the fifth insulative material 160, portions of the first material 106 within the staircase region 104 may selectively be removed (e.g., relative to the fifth insulative material 160, the first conductive structures 134, and the fourth insulative material 138) through the trenches 148. Removal of the first material 106 may expose portions of the dielectric material 136. In some embodiments, exposed portions of the dielectric material 136 may be removed to expose portions of the first conductive structures 134. Removing the first material 106 through the trenches 148 may remove substantially all of the first material 106 from within the staircase region 104. In other embodiments, portions of the first material 106 may remain, such as portions of the first material 106 distal from the trenches 148 and proximate, for example, the first insulative material 118 of the first isolation region 103.

In some embodiments, the first material 106 is removed selective to the fifth insulative material 160, the first conductive structures 134, and the fourth insulative material 138 by exposing the first material 106 to one or both of a dry etch process (e.g., with one or more of ammonia (NH₃), sulfur hexafluoride (SF₆), hydrogen (H₂), and carbon tetrafluoride (CF₄)) or a wet etch process (e.g., with one or more of tetramethylammonium hydroxide (TMAH), deionized water (DIO₃), hydrofluoric acid (HF), ethyltrimethyl ammonium hydroxide (ETMAH) (C₅H₁₅NO)), and one or more amine compounds (e.g., one or more of N-methylethanolamine (NMEA) (C₃H₉NO), monoethanolamine (MEA) (C₂H₇NO), diethanolamine (DEA) (C₄H₁₁NO₂), and triethanolamine (TEA) (C₆H₁₅NO₃)). However, the disclosure is not so limited and the first material 106 may be selectively removed with materials and methods other than those described above.

After removing portions of the first material 106, the exposed portions of the dielectric material 136 may be removed selective to the fourth insulative material 138. In some embodiments, the dielectric material 136 is exposed to a wet etch process, such as to one or more of potassium hydroxide (KOH), hydrofluoric acid (HF), and ammonium fluoride (NH₄F) to selectively remove the dielectric material 136 relative to the fourth insulative material 138.

FIG. 1J and FIG. 1K are a simplified partial top-down view (FIG. 1J) and a simplified partial cross-sectional view (FIG. 1K) of the first microelectronic device structure 100 at a processing stage subsequent to that illustrated in FIG. 1I. FIG. 1K is a simplified cross-sectional view of the first microelectronic device structure 100 taken through section line K-K of FIG. 1J. As described above with reference to FIG. 1E, the first mask material 144 and the oxide material 146 are not illustrated in FIG. 1J for clarity and case of understanding the description. However, it will be understood that the first mask material 144 and the oxide material 146 overlie substantially all of the first microelectronic device structure 100, other than the portions exposed through the trenches 148 (FIG. 1E, FIG. 1I).

With collective reference to FIG. 1J and FIG. 1K, after removing the first material 106 (FIG. 1H) and the portions of the dielectric material 136, a conductive material 150 may be formed at locations corresponding to the first material 106 and the dielectric material 136 previously removed. In some embodiments, the conductive material 150 is formed at the levels of the stack structure 105 vertically between (e.g., in the Z-direction) vertically neighboring (e.g., in the Z-direction) levels of the fifth insulative material 160. The conductive material 150 may be in contact with the first conductive structures 134. By way of non-limiting example, each level of the conductive material 150 may be in contact with a first conductive structure 134 directly vertically above (e.g., in the Z-direction) and a first conductive structure 134 directly vertically below (e.g., in the Z-direction) the level of the conductive material 150. The conductive material 150 may horizontally extend (e.g., in the Y-direction) from the trenches 148 (FIG. 1E, FIG. 1I) to the first conductive structures 134.

In some embodiments, the conductive material 150 one or more of the materials described above with reference to the first conductive structures 134. In some embodiments, the conductive material 150 comprises substantially the same material composition as the first conductive structures 134. In other embodiments, the conductive material 150 comprises a different material composition than the first conductive structures 134.

With continued reference to FIG. 1J and FIG. 1K, after forming the conductive material 150, portions of the conductive material 150 on vertically extending sidewalls (e.g., in the Z-direction) of the trenches 148 (FIG. 1I) and vertically overlying (e.g., in the Z-direction) the first microelectronic device structure 100 may be removed. In some embodiments, at least portions of the oxide material 146 (FIG. 1K) may be removed (e.g., thinned) from upper surfaces of the first microelectronic device structure 100 during removal of the portions of the conductive material 150. In some embodiments, the portions of the conductive material 150 are removed by exposing the conductive material 150 to a wet etch process, such as one or more of ammonium hydroxide, hydrogen peroxide (H₂O₂), sodium hypochlorite (NaOCl), hydrogen fluoride, nitric acid (HNO₃), and sulfuric acid (H₂SO₄).

With collective reference to FIG. 1J and FIG. 1K, horizontally extending (e.g., in the Y-direction) portions of the conductive material 150 remain at the levels of the stack structure 105 after removal of the conductive material 150 from vertically extending sidewalls (e.g., in the Z-direction) defining the trenches 148 (FIG. 1I). The horizontally extending portions of the conductive material 150 may form second conductive structures 154 horizontally extending (e.g., in the Y-direction) at least from the first conductive structures 134 and horizontally terminating at, for example, the trenches 148. Thus, the second conductive structures 154 may individually be in contact with the first conductive structures 134. In some embodiments, the second conductive structures 154 horizontally extend in a horizontal direction (e.g., in the Y-direction) substantially perpendicular to a horizontal direction (e.g., the X-direction) in which the first conductive structures 134 horizontally extend.

With reference to FIG. 1J, the previously illustrated isolated structures 109 of the first material 106 (FIG. 1E) are illustrated with the conductive material 150 which may vertically intervene (e.g., in the Z-direction) between levels of the fifth insulative material 160.

In some embodiments, the second conductive structures 154 intersect the first conductive structures 134 and horizontally extend (e.g., in the Y-direction) beyond lateral boundaries (e.g., in the Y-direction) of the first conductive structures 134. With reference to FIG. 1J, the second conductive structures 154 may be located on both horizontal sides of first conductive structures 134 in a first horizontal direction (e.g., in the Y-direction). The first conductive structures 134 may be located within horizontal boundaries (e.g., in the Y-direction) of the second conductive structures 154. In addition, the second conductive structures 154 may be located within horizontal boundaries (e.g., in the X-direction) of the first conductive structures 134 and the vertical stack structure 135 of the first conductive structures 134.

With continued reference to FIG. 1J and FIG. 1K, after removing the conductive material 150 from surfaces of the first microelectronic device structure 100 and sidewalls of the trenches 148 (FIG. 1E, FIG. 1K), the trenches 148 may be filled with additional portions of the first insulative material 118. Portions of the first insulative material 118 formed over the oxide material 146 may be removed, such as by exposing the first microelectronic device structure 100 to a chemical-mechanical planarization (CMP) process.

FIG. 1L through FIG. 1N are a simplified partial top-down view (FIG. 1L) and simplified partial cross-sectional views (FIG. 1M, FIG. 1N) of the first microelectronic device structure 100 at a processing stage subsequent to that illustrated in FIG. 1K. FIG. 1M is a simplified cross-sectional view of the first microelectronic device structure 100 taken through section line M-M of FIG. 1L. FIG. 1N is a simplified cross-sectional view of the first microelectronic device structure 100 taken through section line N-N of FIG. 1L. For clarity and understanding of the description, FIG. 1N illustrates more levels of the conductive material 150 and the fifth insulative material 160 than FIG. 1M to more clearly illustrate the formation of steps (e.g., steps 165 (FIG. 1S)) of a staircase structure (e.g., staircase structure 175 (FIG. 1W through FIG. 1Z)). It will be understood that FIG. 1M and FIG. 1N are not illustrated to scale with respect to one another.

With collective reference to FIG. 1L through FIG. 1N, the array regions 102 and portions of the staircase region 104 may be covered with one or more mask materials, such as a first buried anti-reflective coating (BARC) material 162 and a first resist material 164. The first BARC material 162 is not illustrated in FIG. 1L since the first BARC material 162 vertically underlies (e.g., in the Z-direction) the first resist material 164. As illustrated in FIG. 1L, substantially all of (e.g., all of) each of the array regions 102 are covered by the first BARC material 162 (FIG. 1M) and the resist material 164; and a majority of the staircase region 104 is covered by the first BARC material 162 and the first resist material 164. By way of non-limiting example, substantially all of the staircase region 104 may be covered by the first BARC material 162 and the first resist material 164, other than portions of a first column 113 of the isolated structures 109. The first column 113 of the isolated structures 109 may be horizontally nearest (e.g., in the X-direction) to one of the array regions 102, and may be horizontally farthest from other of the array regions 102 than the other columns 113 of the isolated structures 109.

In some embodiments, portions of the vertical stack structure 135 of the first conductive structures 134 are covered by the first BARC material 162 and the first resist material 164. In some embodiments, only portions of the second conductive structures 154, such as portions of the second conductive structures 154 distal from the first conductive structures 134 and the vertical stack structure 135 are exposed through the first BARC material 162 and the first resist material 164. In other words, portions of the second conductive structures 154 of a first column 113 of the isolated structures 109 are exposed through the first BARC material 162 and the first resist material 164 and other portions of the first column 113 of the isolated structures 109 are covered by the first BARC material 162 and the first resist material 164.

The first BARC material 162 may be formed of and include one or more of titanium, titanium dioxide, chromium oxide, magnesium fluoride (MgF₂), carbon, alpha-silicon, or an organic material (e.g., a fluorine-containing polymer), a dielectric anti-reflective coating (DARC) material. However, the disclosure is not so limited and the first BARC material 162 may include materials other than those described above.

The first resist material 164 may be formed of and include a methacrylate copolymer with siloxane groups, methyl methacrylate, diazonaphthoquinone (DNQ), a copolymer of tert-butyl methacrylate and 3-heptaisobutyl-POSS-propyl methacrylate, and a negative photoresist (e.g., hydrogen silsesquioxane (HSQ)). However, the disclosure is not so limited and the first resist material 164 may include materials other than those described above.

With reference to FIG. 1M and FIG. 1N, exposed portions of the second conductive structures 154 may be removed through the first BARC material 162 and the first resist material 164. By way of non-limiting example, portions of the vertically uppermost (e.g., in the Z-direction) two levels of the fifth insulative material 160 and the vertically uppermost (e.g., in the Z-direction) level of the second conductive structures 154 may be removed through the first BARC material 162 and the first resist material 164 to expose the second uppermost (e.g., in the Z-direction) second conductive structure 154.

In some embodiments, the levels of the fifth insulative material 160 and the conductive material 150 of the second conductive structures 154 may be removed by dry etching, such as by reactive ion etching (RIE). By way of non-limiting example, the fifth insulative material 160 may be removed by exposing the fifth insulative material 160 to one or more of hydrogen (H₂), carbon tetrafluoride (CF₄), fluoromethane (CH₃F), hexafluoroethane (C₂F₆), octafluoropropane (C₃F₈), and octafluorocyclopentene (C₅F₈). The portions of the levels of the second conductive structures 154 may be removed by exposing the second conductive structure 154 to one or more of sulfur hexafluoride (SF₆), oxygen (O₂), ammonia (NH₃), carbon tetrafluoride, fluoromethane, and bromotrifluoromethane (CBrF₃). However, the disclosure is not so limited and the portions of each of the fifth insulative material 160 and the second conductive structures 154 may be removed by methods other than those described above.

FIG. 1O and FIG. 1P are a simplified partial top-down view (FIG. 1O) and a simplified partial cross-sectional views (FIG. 1P) of the first microelectronic device structure 100 at a processing stage subsequent to that illustrated in FIG. 1L through FIG. 1N. FIG. 1P is a simplified cross-sectional view of the first microelectronic device structure 100 taken through section line P-P of FIG. 1O.

With collective reference to FIG. 1O and FIG. 1P, the first BARC material 162 and portions of the first resist material 164 in the staircase region 104 may be trimmed (e.g., removed) in a horizontal direction (e.g., in the X-direction) to expose a second column 113 of the isolated structures 109.

After exposing the second column 113 of the isolated structures 109, portions of additional levels of the fifth insulative material 160 and the second conductive structures 154 may be removed. The levels of the fifth insulative material 160 and the second conductive structures 154 may be removed as described above with reference to FIG. 1M and FIG. 1N. In some embodiments, portions of two levels of each of the fifth insulative material 160 and the second conductive structures 154 are removed. Removal of the portions of the levels of the fifth insulative material 160 and the second conductive structures 154 lowers the levels of the first column 113 of the isolated structures 109 relative to the second column 113 of the isolated structures 109 and forms steps 165.

Accordingly, steps 165 directly horizontally neighboring (e.g., in the X-direction) one another may be vertically spaced (e.g., in the Z-direction) from one another by two levels of the second conductive structures 154 and two levels of the fifth insulative material 160.

FIG. 1Q through FIG. 1S are a simplified partial top-down view (FIG. 1Q) and simplified partial cross-sectional views (FIG. 1R, FIG. 1S) of the first microelectronic device structure 100 at a processing stage subsequent to that illustrated in FIG. 1O through FIG. 1P. FIG. 1R is a simplified cross-sectional view of the first microelectronic device structure 100 taken through section line R-R of FIG. 1Q. FIG. 1S is a simplified cross-sectional view of the first microelectronic device structure 100 taken through section line S-S of FIG. 1Q.

With collective reference to FIG. 1Q through FIG. 1S, the process of sequentially trimming the first BARC material 162 and portions of the first resist material 164 in the staircase region 104 to expose an additional column 113 of the isolated structures 109 within the staircase region 104; and removing portions of levels (e.g., two levels of each) of the second conductive structures 154 and the fifth insulative material 160 may be repeated to form a preliminary staircase structure 166 comprising the steps 165 vertically descending (e.g., in the Z-direction) in a horizontal direction (e.g., in the X-direction). In some embodiments, each one of the rows 115 of the isolated structures 109 may form one of the preliminary staircase structures 166. In some embodiments, horizontally neighboring (e.g., in the X-direction) steps 165 of the preliminary staircase structure 166 may be vertically spaced (e.g., in the Z-direction) from one another by two levels of each of the second conductive structures 154 and two levels of the fifth insulative material 160.

FIG. 1T through FIG. 1V are a simplified partial top-down view (FIG. 1T) and simplified partial cross-sectional views (FIG. 1U, FIG. 1V) of the first microelectronic device structure 100 at a processing stage subsequent to that illustrated in FIG. 1Q through FIG. 1S. FIG. 1U is a simplified cross-sectional view of the first microelectronic device structure 100 taken through section line U-U of FIG. 1T. FIG. 1V is a simplified cross-sectional view of the first microelectronic device structure 100 taken through section line V-V of FIG. 1T. The cross-sectional view of FIG. 1V is horizontally offset (e.g., in the Y-direction) from the cross-sectional view of FIG. 1S. In particular, the cross-sectional view of FIG. 1V illustrates portions of the second conductive structures 154 horizontally spaced (e.g., in the Y-direction) from the first conductive structures 134 a greater distance than the cross-sectional view of FIG. 1S.

With collective reference to FIG. 1T through FIG. 1V, after forming the preliminary staircase structure 166, the first BARC material 162 (FIG. 1R, FIG. 1S) and the first resist material 164 (FIG. 1Q through FIG. 1S) may be removed from the first microelectronic device structure 100. A second mask material 168 may be formed over portions of the first microelectronic device structure 100, a second BARC material 170 may be formed over the second mask material 168, and a second resist material 172 may be formed over the second BARC material 170.

The second mask material 168, the second BARC material 170, and the second resist material 172 may comprise substantially the same material composition as each of the respective first mask material 144, the first BARC material 162, and the first resist material 164.

With reference to FIG. 1T, substantially all of the array regions 102 may be covered by the second mask material 168, the second BARC material 170, and the second resist material 172 and portions of the staircase region 104 may be exposed through the second mask material 168, the second BARC material 170, and the second resist material 172. In some embodiments, portions of the steps 165 of the preliminary staircase structure 166 (FIG. 1Q, FIG. 1S) may be covered by the second mask material 168, the second BARC material 170, and the second resist material 172; and other portions of the steps 165 may be exposed through the second mask material 168, the second BARC material 170, and the second resist material 172. In some embodiments, about one-half of each step 165 in a horizontal dimension (e.g., in the Y-direction) is exposed through the second mask material 168, the second BARC material 170, and the second resist material 172; and the other about one-half of the horizontal dimension of each of the steps 165 is covered by the second mask material 168, the second BARC material 170, and the second resist material 172.

With reference to FIG. 1U and FIG. 1V, one level of the second conductive structures 154 and one level of the fifth insulative material 160 may be removed at the portions of the steps 165 exposed through the second mask material 168, the second BARC material 170, and the second resist material 172. With reference to FIG. 1U, in some embodiments, the steps 165 horizontally neighboring (e.g., in the Y-direction) one another and extending from the same column 113 of the isolated structures 109 are vertically spaced (e.g., in the Z-direction) from one another by one level of the second conductive structures 154 and one level of the fifth insulative material 160.

Removal of one level of the second conductive structures 154 and one level of the fifth insulative material 160 may form a staircase structure 175 from the preliminary staircase structure 166 (FIG. 1Q, FIG. 1S). The staircase structure 175 may comprise vertical levels of the second conductive structures 154, and the vertical levels of the first conductive structures 134 of a portion of the vertical stack structure 135 (e.g., the portion of the vertical stack structure 135 horizontally extending (e.g., in the X-direction) through the staircase region 104). Each level of the second conductive structures 154 horizontally extends (e.g., in the Y-direction) from a level of a first conductive structure 134 of the vertical stack structure 135 (FIG. 1W) of first conductive structures 134.

FIG. 1W through FIG. 1Z are a simplified partial top-down view (FIG. 1W), simplified partial views (FIG. 1X, FIG. 1Y), and a simplified partial perspective view (FIG. 1Z) of the first microelectronic device structure 100 at a processing stage subsequent to that illustrated in FIG. 1T through FIG. 1V. FIG. 1X is a simplified partial cross-sectional view of the first microelectronic device structure 100 taken through section line X-X of FIG. 1W. FIG. 1Y is a simplified partial cross-sectional view of the first microelectronic device structure 100 taken through section line Y-Y of FIG. 1W. FIG. 1Z is a simplified perspective view of the first microelectronic device structure 100 illustrating box Z of FIG. 1W.

With reference to FIG. 1W through FIG. 1Y, after forming the steps 165 in the Y-direction, the second mask material 168 (FIG. 1U), the second BARC material 170 (FIG. 1U), and the second resist material 172 (FIG. 1T, FIG. 1U) may be removed from the first microelectronic device structure 100; a sixth insulative material 174 (not illustrated in FIG. 1W for clarity and case of understanding the description) may be formed over the first microelectronic device structure 100; and conductive contact structures 176 may be formed through the sixth insulative material 174 and in contact with the second conductive structures 154 of the steps 165 of the staircase structure 175.

With collective reference to FIG. 1W through FIG. 1Z, the staircase structure 175 includes sub-staircase structures 177 comprising the second conductive structures 154 each individually comprising steps 165 vertically descending (e.g., in the Z-direction) in a first horizontal direction (e.g., the Y-direction). In addition, and as illustrated in FIG. 1W and FIG. 1Y, the steps 165 of horizontally neighboring (e.g., in the X-direction) sub-staircase structures 177 are horizontally spaced (e.g., in the X-direction) from one another by the first insulative material 118 and vertically descend (e.g., in the Z-direction) in a second horizontal direction (e.g., in the X-direction).

In some embodiments, each of the second conductive structures 154 horizontally extends (e.g., in the Y-direction) in a direction substantially perpendicular to a horizontal direction (e.g., in the X-direction) in which the first conductive structures 134 of the vertical stack structure 135 extend. In some such embodiments, the sub-staircase structures 177 horizontally extend (e.g., in the Y-direction) in a direction substantially perpendicular to a horizontal direction (e.g., in the X-direction) in which the first conductive structures 134 of the vertical stack structure 135 extend.

In some embodiments, the first conductive structures 134 of the vertical stack structures 135 of horizontally neighboring (e.g., in the Y-direction) staircase structures 175 extend substantially parallel to one another. In addition, the second conductive structures 154 of sub-staircase structures 177 of a first staircase structure 175 and horizontally neighboring (e.g., in the X-direction) one another extend substantially parallel to one another and exhibit substantially the same horizontal dimension (e.g., in the Y-direction). Second conductive structures 154 of sub-staircase structures 177 of a second staircase structure 175 extend substantially parallel to one another and the second conductive structures 154 of the sub-staircase structures 177 of the first staircase structure 175.

FIG. 1Z illustrates portions of two of the staircase structures 175 including staircase structures 175 horizontally between (e.g., in the Y-direction) two of the first isolation regions 103 (FIG. 1W). For clarity and case of understanding the description, the vertical stack structure 135 of one of the staircase structures 175 is not illustrated in FIG. 1Z to more clearly illustrate the sub-staircase structures 177 of the staircase structures 175.

With reference to FIG. 1Z, the staircase structures 175 may optically mirror one another. By way of non-limiting example, in some embodiments, a first staircase structure 175 includes sub-staircase structures 177 including steps 165 vertically descending (e.g., in the Z-direction) in a first horizontal direction (e.g., in the positive Y-direction) and a second staircase structure 175 includes sub-staircase structures 177 including steps 165 vertically ascending (e.g., in the Z-direction) in the first horizontal direction (e.g., in the positive Y-direction) and vertically descending (e.g., in the Z-direction) in the opposite horizontal direction (e.g., in the negative Y-direction). In some embodiments, the first staircase structure 175 and the second staircase structure 175 include steps 165 vertically descending (e.g., in the Z-direction) in a second horizontal direction (e.g., in the X-direction, such as the positive X-direction).

In some embodiments, sub-staircase structures 177 of a first staircase structure 175 exhibit positive slope; and the sub-staircase structures 177 of a second sub staircase structure 177 exhibit negative slope of substantially equal magnitude and opposite to the positive slope. In some embodiments, a phantom line extending from a top of each of the sub-staircase structures 177 of the first staircase structure 175 to a bottom of the sub-staircase structures 177 may have positive slope, and another phantom line extending from a top of each of the sub-staircase structures 177 of the second staircase structure 175 to a bottom of the sub-staircase structures may have negative slope. For example, with reference to FIG. 1X, the sub-staircase structure 177 on the left may exhibit negative slope and the sub-staircase structure 177 on the right may exhibit positive slope. In some embodiments, the positive slope and the negative slope have the same magnitude (e.g., the positive slope may be X, and the negative slope may be −X, where X is a number corresponding to the change in the vertical dimension (e.g., in the Z-direction) divided by the change in the horizontal dimension (e.g., in the X-direction) of the respective sub-staircase structure 177).

With reference to FIG. 1X, the sub-staircase structures 177 of a first staircase structure 175 and a second staircase structure 175 facing one another may form a stadium structure 181 comprising a sub-staircase structure 177 of the first stadium structure 181 and a corresponding sub-staircase structure 177 of the second staircase structure 175. In some embodiments, a pair of facing staircase structures 175 define a quantity of stadium structures 181 corresponding to a quantity of the sub-staircase structures 177 of each of the stadium structures 181.

In some embodiments, each of the steps 165 directly contacts one of the conductive contact structures 176. In some embodiments, each of the sub-staircase structures 177 comprises two levels of exposed portions of the second conductive structures 154. In some such embodiments, each of the sub-staircase structures 177 is directly contacted by two of the conductive contact structures 176 (e.g., one conductive contact structure 176 at each of the steps 165 of the sub-staircase structures 177).

In some embodiments, and with reference to FIG. 1W, one-half of the conductive contact structures 176 in contact with the steps 165 of a staircase structure 175 may be horizontally aligned with one another in a horizontal direction (e.g., in the Y-direction) and may be horizontally offset (e.g., in the X-direction) from the other one-half of the conductive contact structures 176. In some embodiments, the conductive contact structures 176 on the steps 165 of a stadium structure 181 are horizontally aligned with one another in a second horizontal direction (e.g., in the X-direction).

In some embodiments, the steps 165 of horizontally neighboring (e.g., in the X-direction) sub-staircase structures 177 may be vertically spaced (e.g., in the Z-direction) from one another by two levels of the second conductive structures 154 and two levels of the fifth insulative material 160. By way of non-limiting example, in some embodiments, a first step 165 horizontally nearest (e.g., in the Y-direction) the vertical stack structure 135 of conductive structures 134 of a first sub-staircase structure 177 is vertically offset (e.g., in the Z-direction) from a first step 165 horizontally nearest (e.g., in the Y-direction) the vertical stack structure 135 of conductive structures 134 of a second sub-staircase structure 177 by two levels of the conductive material 150 of the second conductive structures 154 and two levels of the fifth insulative material 160. In addition, a second step 165 horizontally farthest (e.g., in the Y-direction) from the vertical stack structure 135 of conductive structures 134 of the first sub-staircase structure 177 may be vertically offset (e.g., in the Z-direction) from a second step 165 horizontally farthest (e.g., in the Y-direction) from the vertical stack structure 135 of conductive structures 134 of the second sub-staircase structure 177 by two levels of the conductive material 150 of the second conductive structures 154 and two levels of the fifth insulative material 160. The first step 165 of the first sub-staircase structure 177 may be vertically offset (e.g., in the Z-direction) from the second step 165 of the second sub-staircase structure 177 by three levels of the conductive material 150 of the second conductive structures 154 and three levels of the fifth insulative materials 160; and the second step 165 of the first sub-staircase structure 177 may be vertically offset (e.g., in the Z-direction) from the first step of the second sub-staircase structure 177 by one level of the conductive material 150 of the second conductive structures 154 and one level of the fifth insulative material 160.

Although FIG. 1W through FIG. 1Y illustrate that the staircase structures 175 individually include fourteen (14) steps 165 (e.g., seven (7) sub-staircase structures 177 each individually comprising two (2) steps 165), the disclosure is not so limited. In other embodiments, the staircase structures 175 each individually include a desired quantity of the steps 165, such as within a range from thirty-two (32) of the steps 165 to two hundred fifty-six (256) of the steps 165. In some embodiments, the staircase structures 175 each individually include sixty-four (64) of the steps 165. In other embodiments, the staircase structures 175 each individually include ninety-six (96) or more of the steps 165. In other embodiments, the staircase structures 175 each individually include a different number of the steps 165, such as less than sixty-four (64) of the steps 165 (e.g., less than or equal to sixty (60) of the steps 165, less than or equal to fifty (50) of the steps 165, less than about forty (40) of the steps 165, less than or equal to thirty (30) of the steps 165, less than or equal to twenty (20) of the steps 165, less than or equal to ten (10) of the steps 165); or greater than sixty-four (64) of the steps 165 (e.g., greater than or equal to seventy (70) of the steps 165, greater than or equal to one hundred (100) of the steps 165, greater than or equal to about one hundred twenty-eight (128) of the steps 165, greater than two hundred fifty-six (256) of the steps 165).

The conductive contact structures 176 may be formed of and include conductive material, such as one or more of the materials described above with reference to the first conductive structures 134. In some embodiments, the conductive contact structures 176 individually comprise substantially the same material composition as the first conductive structures 134. In some embodiments, the conductive contact structures 176 individually comprise tungsten.

Referring to FIG. 1W and FIG. 1Z, in some embodiments, a horizontal distance in a horizontal direction (e.g., in the X-direction) between a vertically uppermost (e.g., in the Z-direction) step 165 of a staircase structure 175 and a first array region 102 may be about the same as a horizontal distance in the horizontal direction (e.g., in the X-direction) between a second vertically lowest (e.g., in the Z-direction) step 165 of the staircase structure 175 and a second array region 102.

The sixth insulative material 174 may be formed of and include insulative material, such as one or more of the materials described above with reference to the second insulative material 114. In some embodiments, the sixth insulative material 174 comprises silicon dioxide.

With continued reference to FIG. 1X and FIG. 1Y, conductive pad structures 180 may be formed in contact with the conductive contact structures 176. The conductive pad structures 180 may individually be formed of and comprise conductive material, such as one or more of the materials described above with reference to the first conductive structures 134. In some embodiments, the conductive pad structures 180 individually comprise tungsten.

With reference to FIG. 1W, the sub-staircase structures 177 and the steps 165 may have a horizontal width D2 (e.g., in the X-direction) within a range of from about 150 nm to about 250 nm, such as from about 150 nm to about 200 nm, or from about 200 nm to about 250 nm. In some embodiments, the horizontal width D2 is about 200 nm. However, the disclosure is not so limited and the horizontal width D2 may be different than those described above.

In some embodiments, a horizontal length D3 (e.g., in the Y-direction) of the sub-staircase structures 177 from the vertical stack structure 135 to terminal ends of the sub-staircase structures 177 may be within a range of from about 500 nm to about 650 nm, such as from about 500 nm to about 550 nm, from about 550 nm to about 600 nm, or from about 600 nm to about 650 nm. In some embodiments, the horizontal length D3 is about 580 nm. However, the disclosure is not so limited and the horizontal length D3 may be different than those described above. The horizontal length D3 may correspond to the horizontal length of two (2) steps 165. In some such embodiments, the horizontal length of each step 165 is about one-half of the horizontal length D3.

With continued reference to FIG. 1W, in some embodiments, a horizontal spacing D4 (e.g., in the X-direction) between horizontally neighboring (e.g., in the X-direction) sub-staircase structures 177. In some embodiments, the horizontal spacing D4 between horizontally neighboring (e.g., in the X-direction) sub-staircase structures 177 is less than the horizontal width D2 of the sub-staircase structures 177. In other embodiments, the horizontal spacing D4 between horizontally neighboring (e.g., in the X-direction) sub-staircase structures 177 is greater than the horizontal width D2 of the sub-staircase structures 177.

FIG. 2A through FIG. 2E are a simplified partial top-down view (FIG. 2A) and simplified partial cross-sectional views (FIG. 2B through FIG. 2E) illustrating a method of forming a microelectronic device 200 from the first microelectronic device structure 100 and a second microelectronic device structure 250, in accordance with embodiments of the disclosure. FIG. 2A is a simplified partial top-down view of the first microelectronic device structure 100 following the processing stage illustrated with reference to FIG. 1W through FIG. 1Z. FIG. a2B is a simplified partial cross-sectional view of the first microelectronic device structure 100 taken through section line B-B of FIG. 2A.

Storage devices 210 (e.g., capacitors) may be formed within the array regions, each storage device 210 individually in contact with the access devices 130. The storage devices 210 may form a vertical stack of storage devices 210 comprising vertical levels of storage devices 210 individually in contact with a level of an access device 130 of the vertical stack of access devices 130. Each access device 130 in contact with a storage device 210 may form a memory cell 220 and the vertical stack of access devices 130 coupled to the vertical stack of storage devices 210 may be form a corresponding vertical stack of memory cells 220. Accordingly, the vertical stack of memory cells 220 may individually include be vertically spaced (e.g., in the Z-direction) levels of memory cells 220, each memory cell 220 individually comprising a storage device 210 horizontally neighboring (e.g., in the Y-direction) an access device 130.

Although FIG. 2A illustrates that each of the array regions 102 individually comprises sixteen (16) vertical stacks of memory cells 220 (e.g., four (4) rows and four (4) columns of the vertical stacks of memory cells 220), the disclosure is not so limited, and the array regions 102 may individually include greater than sixteen vertical stacks of memory cells 220.

With continued reference to FIG. 2A and FIG. 2B, in some embodiments, the storage devices 210 are in contact with a conductive plate structure 215. By way of non-limiting example, the second electrode 214 of the storage devices 210 are in contact with the conductive plate structure 215. The conductive plate structure 215 may be formed of and include conductive material, such as one or more of the materials of an electrode (e.g., a second electrode 214) of the storage devices 210. In some embodiments, the conductive plate structure 215 comprises substantially the same material composition as an electrode of the storage devices 210. In other embodiments, the conductive plate structure 215 comprises a different material composition than the electrodes of the storage devices 210. The conductive plate structures 215 may be referred to herein as “conductive plates” or “ground structures.” The conductive plate structures 215 horizontally extend (e.g., in the X-direction) as conductive plates. In some embodiments, and with reference to FIG. 2A, the conductive plate structures 215 horizontally extend in substantially the same direction and are substantially parallel to the conductive structures 134 of the vertical stack structure 135. The conductive plate structures 215 may be horizontally between (e.g., in the Y-direction) vertical stacks of memory cells 220, such as between vertical stacks of storage devices 210.

Each of the storage devices 210 individually comprises a first electrode 212 (also referred to herein as an “outer electrode,” “a first electrode plate,” or a “first node structure”), a second electrode 214 (also referred to herein as an “inner electrode,” “a second electrode plate,” or a “second node structure”), and a dielectric material 216 between the first electrode 212 and the second electrode 214. In some such embodiments, the storage devices 210 individually comprise capacitors. However, the disclosure is not so limited and in other embodiments, the storage devices 210 may each individually comprise other structures, such as, for example, phase change memory (PCM), resistance random-access memory (RRAM), conductive-bridging random-access memory (conductive bridging RAM), or another structure for storing a logic state.

At least a portion of each storage device 210 is in contact with a horizontally neighboring (e.g., in the X-direction) access device 130. In some embodiments, the first electrode 212 of each storage device 210 contacts a horizontally neighboring access device 130.

The first electrode 212 may be formed of and include conductive material such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium), polysilicon, and other materials exhibiting electrical conductivity. In some embodiments, the first electrode 212 comprises titanium nitride.

The second electrode 214 may be formed of and include conductive material. In some embodiments, the second electrode 214 comprises one or more of the materials described above with reference to the first electrode 212. In some embodiments, the second electrode 214 comprises substantially the same material composition as the first electrode 212.

The dielectric material 216 may be formed of and include one or more of silicon dioxide (SiO₂), silicon nitride (Si₃N₄), polyimide, titanium dioxide (TiO₂), tantalum oxide (Ta₂O₅), aluminum oxide (Al₂O₃), an oxide-nitride-oxide material (e.g., silicon dioxide-silicon nitride-silicon dioxide), strontium titanate (SrTiO₃) (STO), barium titanate (BaTiO₃), hafnium oxide (HfO₂), zirconium oxide (ZrO₂), a ferroelectric material (e.g., ferroelectric hafnium oxide, ferroelectric zirconium oxide, lead zirconate titanate (PZT)), and a high-k dielectric material.

The second electrode 214 may be in contact with one of the conductive plate structures 215 of a vertical stack of memory cells 220. In some embodiments, the second electrodes 214 are substantially integral with the conductive plate structures 215. With reference to FIG. 2B, in some embodiments, the second electrodes 214 of horizontally neighboring (e.g., in the X-direction) vertical stacks of storage devices 210 contact the same conductive plate structure 215. In some embodiments, the conductive plate structures 215 are individually formed of conductive material, such as one or more of the materials of the second electrode 214. In some embodiments, the conductive plate structures 215 comprise substantially the same material composition as the second electrode 214. In other embodiments, the conductive plate structures 215 comprise a different material composition than the second electrode 214.

The quantity of steps 165 may correspond to the quantity of the levels of the conductive material 150 (e.g., the levels of the first conductive structures 134 and the levels of the sixth insulative material 174). In some embodiments, a quantity of the steps 165 of the staircase structures 175 equals the number of levels of the memory cells. In some such embodiments, each vertical stack of memory cells 220 of the first microelectronic device structure 100 individually includes a corresponding quantity memory cells 220 as the quantity of the steps 165.

With reference to FIG. 2A, the staircase region 104 is horizontally between (e.g., in the X-direction) horizontally neighboring array regions 102 including the vertical stacks of memory cells 220. Staircase structures 175 are located horizontally between (e.g., in the X-direction) the array regions 102. The staircase structures 175 individually include a vertical stack structure 135 of the first conductive structures 134 that horizontally extend (e.g., in the X-direction) through the staircase region 104 and into each of the array regions 102.

In use and operation, the first conductive structures 134 may individually be configured to provide sufficient voltage to the channel region 132 directly vertically neighboring (e.g., in the Z-direction) the respective access device 130 to electrically couple a storage device 210 horizontally neighboring (e.g., in the Y-direction) and associated with the access device 130 to, for example, a conductive pillar structure vertically extending proximate the vertical stack of access devices 130 of the vertical stack of memory cells 220. Stated another way, each of the first conductive structures 134 may individually comprise a gate structure configured to provide a sufficient voltage to the channel region 132 vertically neighboring (e.g., in the Z-direction) the first conductive structure 134 to electrically couple the access device 130 including the channel region 132 to the horizontally neighboring (e.g., in the Y-direction) storage device 210. Since the first conductive structures 134 are configured to provide a voltage to the memory cells 220 (e.g., by means of a voltage applied to the corresponding second conductive structures 154 by means of the respective conductive contact structure 176), the first conductive structures 134 may individually be referred to herein as “first conductive lines,” “access lines,” or “word lines.”

Accordingly, the first conductive structures 134 may be driven (e.g., a voltage may be applied to the first conductive structures 134) of the memory cells 220 of two different array regions 102 by applying a voltage to one or more of the conductive contact structures 176 located in the staircase structure 175 in the staircase region 104. In some embodiments, each individual first conductive structure 134 is configured to provide a voltage (e.g., a drive voltage, an access voltage) to levels of memory cells 220 in each of two array regions 102, the array regions 102 horizontally separated from one another by the staircase region 104.

Still referring to FIG. 2A and FIG. 2B, global digit lines 230 may be formed over the vertical stacks of memory cells 220. Each global digit line 230 may be configured to be in electrical communication with more than one of the conductive pillar structures 140 by means of, for example, a transistor (e.g., a multiplexer) of the semiconductive material 112. The transistor of the semiconductive material 112 may be in contact with conductive interconnect structures 232 that are in contact with the global digit line 230 and the conductive pillar structures 140. Routing structures 234 provide a conductive path from one of the conductive interconnect structures 232 in contact with the transistor of the semiconductive material 112 and a conductive interconnect structure 232 in contact with the conductive pillar structure 140.

Each of the global digit lines 230 may be in contact with more than one vertical stacks of memory cells 220 (e.g., more than one conductive pillar structure (local digit line) 140 of different vertical stacks of memory cells 220).

The global digit lines 230 may also be referred to as “conductive lines.” The global digit lines 230 may be formed vertically over (e.g., in the Z-direction) and in electrical communication with the conductive pillar structures 140 by means of transistors within the semiconductive material 112. With reference to FIG. 2A, the global digit lines 230 are located within the array regions 102 and extend in a horizontal direction (e.g., the Y-direction) substantially perpendicular to the vertical stack structures 135.

With continued reference to FIG. 2B, in some embodiments, the conductive plate structure 215 is in configured to be in electrical communication with transistors of the semiconductive material 112 by means of additional ones of the conductive interconnect structures 232 and the routing structures 234.

Each of the conductive interconnect structures 232 and the routing structures 234 individually comprises conductive material, such as one or more of the materials described above with reference to the first conductive structures 134. In some embodiments, each of the conductive interconnect structures 232 and the routing structures 234 individually comprises tungsten.

In some embodiments, the steps 165 of the staircase structures 175 vertically descend (e.g., in the Z-direction) in a horizontal direction (e.g., in the Y-direction) substantially perpendicular to the conductive plate structures 215. In some embodiments, the conductive plate structures 215 are horizontally between (e.g., in the Y-direction) horizontally neighboring (e.g., in the Y-direction) staircase structures 175 that form stadium structures 181 (FIG. 1W).

FIG. 2C through FIG. 2E are simplified partial cross-sectional views illustrating a microelectronic device 200 formed from the first microelectronic device structure 100 and a second microelectronic device structure 250 after attaching the second microelectronic device structure 250 to the first microelectronic device structure 100. FIG. 2C is a simplified cross-sectional view of the microelectronic device 200 and illustrates the same cross-sectional view of the first microelectronic device structure 100 illustrated in FIG. 2B, but at a processing stage subsequent to that of FIG. 2B. FIG. 2D is a simplified cross-sectional view of the microelectronic device 200 and illustrates the same cross-sectional view of the first microelectronic device structure 100 illustrated in FIG. 1W, but at a processing stage subsequent to that of FIG. 1W. FIG. 2E is a simplified cross-sectional view of the microelectronic device 200 and illustrates the same cross-sectional view of the first microelectronic device structure 100 illustrated in FIG. 1Y, but at a processing stage subsequent to that of FIG. 1Y.

By way of non-limiting example, the second microelectronic device structure 250 may be attached to the first microelectronic device structure 100 by oxide-to-oxide bonding. In some such embodiments, an oxide material of the second microelectronic device structure 250 is brought into contact with an oxide material of the first microelectronic device structure 100 and the first microelectronic device structure 100 and the second microelectronic device structure 250 are exposed to annealing conditions to form bonds (e.g., oxide-to-oxide bonds) between the oxide material of the first microelectronic device structure 100 and the oxide material of the second microelectronic device structure 250.

The second microelectronic device structure 250 may include control logic devices (e.g., CMOS devices) and circuitry configured for effectuating control operations for the memory cells 220. By way of non-limiting example, the second microelectronic device structure 250 may include one or more sub word line driver regions, one or more socket regions, and one or more additional CMOS regions including one or more of one or more sense amplifier devices (e.g., equalization (EQ) amplifiers, isolation (ISO) amplifiers, NMOS sense amplifiers (NSAs), PMOS sense amplifiers (PSAs)), column decoders, multiplexer control logic devices, sense amplifier drivers, main word line driver devices, row decoder devices, and row select devices.

With reference to FIG. 2C, the second microelectronic device structure 250 may include one or more sense amplifier device regions 202 vertically overlying (e.g., in the Z-direction) and within horizontal boundaries of (e.g., within a horizontal area of) the vertical stacks of memory cells 220. The sense amplifier device regions 202 may include transistor structures configured to be in electrical communication with the global digit lines 230 by means of conductive interconnect structures 204. In some embodiments, the sense amplifier device regions 202 include sense amplifier devices (e.g., equalization (EQ) amplifiers, isolation (ISO) amplifiers, NMOS sense amplifiers (NSAs), PMOS sense amplifiers (PSAs)).

With reference to FIG. 2D and FIG. 2E, the second microelectronic device structure 250 may include one or more sub word line driver regions 206 vertically overlying (e.g., in the Z-direction) and within horizontal boundaries of the staircase structures 175, such as vertically overlying the conductive contact structures 176 and the conductive pad structures 180.

The sub word line driver regions 206 may include transistor structures configured to be in electrical communication with the first conductive structures 134 by mean of conductive interconnect structures 208 that are in contact with the conductive pad structures 180 and the second conductive structures 154. By way of non-limiting example, the sub word line drivers may be operably coupled to the vertical stacks of memory cells 220 by means of the conductive interconnect structures 208, the conductive pad structures 180, the conductive contact structures 176, the second conductive structures 154, and the first conductive structures 134.

Each of the conductive interconnect structures 204 and the conductive interconnect structures 208 individually formed of and include conductive material, such as one or more of the conductive materials described above with reference to the conductive pillar structures 140. In some embodiments, the conductive interconnect structures 204 and the conductive interconnect structures 208 individually comprise tungsten. In other embodiments, the conductive interconnect structures 204 and the conductive interconnect structures 208 individually comprise copper.

In some embodiments, the sub word line driver regions 206 are located within horizontal boundaries (e.g., in the X-direction, in the Y-direction) of the staircase region 104 of the first microelectronic device structure 100.

Thus, in accordance with some embodiments, a microelectronic device comprises a first microelectronic device structure comprising a first memory array region comprising first vertical stacks of first dynamic random access memory (DRAM) cells, each of the first DRAM cells comprising a storage device of a vertical stack of storage devices and a horizontally neighboring access device of a vertical stack of access devices, a second memory array region comprising second vertical stacks of second DRAM cells, and a staircase region substantially horizontally centered in a first direction between the first memory array region and the second memory array region. The staircase region comprises a vertical stack of first conductive structures horizontally extending through the staircase region in the first direction, the first conductive structures in contact with the first DRAM cells and the second DRAM cells, and sub-staircase structures individually comprising second conductive structures horizontally extending from the vertical stack of first conductive structures in a second direction, vertically uppermost ones of the second conductive structures of each sub-staircase structure defining steps of the sub-staircase structure, horizontally neighboring ones of the sub-staircase structures substantially evenly horizontally separated from one another in the first direction.

Furthermore, in accordance with additional embodiments of the disclosure, a microelectronic device comprises a first memory array region and a second memory array region. Each of the first memory array region and the second memory array region comprises vertical stacks of access devices, vertical stacks of storage devices horizontally neighboring the vertical stacks of access devices, and a portion of a vertical stack structure comprising substantially linear first conductive structures horizontally extending through the vertical stacks of memory cells, the substantially linear first conductive structures neighboring the memory cells of the vertical stack of memory cells. The microelectronic device further comprises a staircase region horizontally between the first memory array region and the second memory array region. The staircase region comprises a staircase structure comprising an additional portion of the vertical stack structure horizontally extending in a first direction from the first memory array region, through the staircase region, and to the second memory array region, and sub-staircase structures horizontally extending from the vertical stack structure in a second direction different than the first direction, the sub-staircase structures individually comprising second conductive structures defining steps of the sub-staircase structures, the steps of the sub-staircase structures vertically descending in the second horizontal direction.

Moreover, in accordance with some embodiments of the disclosure, a memory device comprises a first memory array and a second memory array, the first memory array and the second memory array individually comprising vertical stacks of dynamic random access memory (DRAM) cells, each of the DRAM cells comprising a storage device horizontally neighboring an access device. The memory device further comprises a staircase structure horizontally between the first memory array and the second memory array, the staircase structure comprising a vertical stack structure comprising first conductive structures vertically spaced from one another and horizontally extending in a first direction from the first memory array to the second memory array, and sub-staircase structures comprising second conductive structures horizontally extending in a second horizontal direction. Each of the second conductive structures is in contact with a corresponding one of the first conductive structures of the vertical stack structure. Each of the sub-staircase structures comprises a different quantity of the second conductive structures than each other of the sub-staircase structures, and steps of each of the sub-staircase structures are individually defined by an uppermost two of the second conductive structures of the sub-staircase structure.

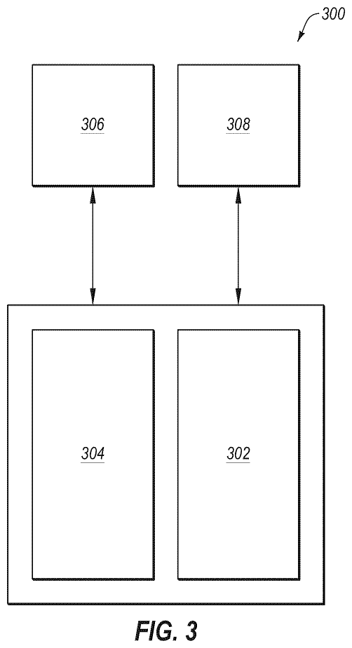

Structures, assemblies, and devices in accordance with embodiments of the disclosure may be included in electronic systems of the disclosure. For example, FIG. 3 is a block diagram of an illustrative electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 300 includes at least one memory device 302. The memory device 302 may comprise, for example, an embodiment of one or more of a microelectronic device structure, a microelectronic device structure assembly, a relatively larger microelectronic device structure assembly, and a microelectronic device previously described herein with reference to FIG. 1A through FIG. 2E. The electronic system 300 may further include at least one electronic signal processor device 304 (often referred to as a “microprocessor”). The electronic signal processor device 304 may, optionally, include an embodiment of one or more of a microelectronic device structure, a microelectronic device structure assembly, a relatively larger microelectronic device structure assembly, and a microelectronic device previously described herein with reference to FIG. 1A through FIG. 2E. While the memory device 302 and the electronic signal processor device 304 are depicted as two (2) separate devices in FIG. 3, in additional embodiments, a single (e.g., only one) memory/processor device having the functionalities of the memory device 302 and the electronic signal processor device 304 is included in the electronic system 300. In such embodiments, the memory/processor device may include one or more of a microelectronic device structure, a microelectronic device structure assembly, a relatively larger microelectronic device structure assembly, and a microelectronic device previously described herein with reference to FIG. 1A through FIG. 3E. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, one or more of a monitor, a display, a printer, an audio output jack, and a speaker. In some embodiments, the input device 306 and the output device 308 may comprise a single touchscreen device that can be used both to input information to the electronic system 300 and to output visual information to a user. The input device 306 and the output device 308 may communicate electrically with one or more of the memory device 302 and the electronic signal processor device 304.

Thus, in accordance with embodiments of the disclosure, an electronic system comprises an input device, an output device, a processor device operably coupled to the input device and the output device, and a memory device operably coupled to the processor device. The memory device comprises a first microelectronic device structure comprising a first array region comprising first vertical stacks of memory cells comprising first vertical stacks of access devices horizontally neighboring first vertical stacks of access devices, a second array region comprising second vertical stacks of memory cells comprising second vertical stacks of access devices horizontally neighboring second vertical stacks of access devices, and a staircase region horizontally between the first array region and the second array region and comprising staircase structures. At least one staircase structure comprises a vertical stack comprising first conductive structures horizontally extending through the staircase region and through the first array region and the second array region, and sub-staircase structures comprising second conductive structures horizontally extending substantially perpendicular to the vertical stack, the sub-staircase structures individually comprising steps vertically descending in a horizontal direction extending away from the vertical stack and defined by edges of the second conductive structures. The staircase region further comprises conductive contact structures individually in contact with one of the second conductive structures at the steps. The memory device further comprises a second microelectronic device structure attached to the first microelectronic device structure. The second microelectronic device structure comprises sub word line drivers vertically above the sub-staircase structures and within horizontal boundaries of the staircase region, the sub word line drivers individually operably coupled to the first vertical stacks of memory cells and the second vertical stacks of memory cells by means of the conductive contact structures.

The materials described herein may be formed by conventional techniques including, but not limited to, spin coating, blanket coating, chemical vapor deposition (CVD), atomic layer deposition (ALD), plasma enhanced ALD, physical vapor deposition (PVD), plasma enhanced chemical vapor deposition (PECVD), or low pressure chemical vapor deposition (LPCVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

As used herein, “semiconductor material” or “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “in electrical communication” when used with reference to a first component or structure with respect to a second component or structure means and includes that in use and operation, the first component or structure is configured to be electrically connected to the second component. By way of non-limiting example, when a first component is in electrical communication with a second component, in use and operation electrons flow between the first component and the second component, such as responsive to receipt of an input voltage (e.g., to the first component). A first component may be in electrical communication with a second component without directly contacting the second component; or may be in electrical communication with the second component by directly contacting the second component.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A microelectronic device, comprising:
a first microelectronic device structure, comprising:
a first memory array region comprising first vertical stacks of first dynamic random access memory (DRAM) cells, each of the first DRAM cells comprising a storage device of a vertical stack of storage devices and a horizontally neighboring access device of a vertical stack of access devices;
a second memory array region comprising second vertical stacks of second DRAM cells;
a staircase region substantially horizontally centered in a first direction between the first memory array region and the second memory array region, the staircase region comprising:
a staircase structure comprising:
a vertical stack of first conductive structures horizontally extending through the staircase region in the first direction, the first conductive structures in contact with the first DRAM cells and the second DRAM cells; and
sub-staircase structures individually comprising second conductive structures horizontally extending from the vertical stack of first conductive structures in a second direction,
vertically uppermost ones of the second conductive structures of each sub-staircase structure defining steps of the sub-staircase structure,
horizontally neighboring ones of the sub-staircase structures substantially evenly horizontally separated from one another in the first direction.

2. The microelectronic device of claim 1, further comprising:
conductive contact structures individually in contact with the second conductive structure of each step of the sub-staircase structures; and
a second microelectronic device structure attached to the first microelectronic device structure and comprising a sub word line driver region vertically overlying and within a horizontal area of the staircase region, the sub word line driver region comprising sub word line drivers configured to provide a voltage to the first memory array region and the second memory array region by means of the conductive contact structures.

3. The microelectronic device of claim 1, wherein the first conductive structures comprise word lines configured to provide a voltage to the vertical stack of access devices of the first memory array region and the vertical stack of access devices of the second memory array region.

4. The microelectronic device of claim 1, wherein a vertical height of the staircase structures decreases as the staircase structures extend away from the first memory array region in the first direction.

5. The microelectronic device of claim 1, wherein each of the sub-staircase structures defines a pair of the steps of the staircase structure.

6. The microelectronic device of claim 1, wherein a vertical height of each of the sub-staircase structures is different than a vertical height of each other of the sub-staircase structures.

7. The microelectronic device of claim 1, wherein the first conductive structures horizontally extend in substantially linear paths through the first memory array region, the second memory array region, and the staircase region.

8. The microelectronic device of claim 1, wherein pairs of the first conductive structures are vertically spaced from one another by an insulative structure.

9. A memory device, comprising:
a first memory array region and a second memory array region, each of the first memory array region and the second memory array region comprising vertical stacks of memory cells comprising:
vertical stacks of access devices;
vertical stacks of storage devices horizontally neighboring the vertical stacks of access devices; and
a portion of a vertical stack structure comprising substantially linear first conductive structures horizontally extending through the vertical stacks of memory cells, the substantially linear first conductive structures neighboring the memory cells of the vertical stack of memory cells; and
a staircase region horizontally between the first memory array region and the second memory array region, the staircase region comprising a staircase structure comprising:
an additional portion of the vertical stack structure horizontally extending in a first direction from the first memory array region, through the staircase region, and to the second memory array region; and
sub-staircase structures horizontally extending from the vertical stack structure in a second direction different than the first direction,
the sub-staircase structures individually comprising second conductive structures defining steps of the sub-staircase structures,
the steps of the sub-staircase structures vertically descending in the second horizontal direction.

10. The memory device of claim 9, wherein the steps of the sub-staircase structures vertically descend in the second direction away from the vertical stack structure.

11. The memory device of claim 9, wherein some of the steps of sub-staircase structures nearer to the first memory array region are vertically higher than some other of the steps of the sub-staircase structures nearer to the second memory array region.

12. The memory device of claim 9, wherein a quantity of the sub-staircase structures is about one-half a quantity of the first conductive structures.

13. The memory device of claim 9, wherein each of the sub-staircase structures comprises a different quantity of the second conductive structures than each other of the sub-staircase structures.

14. The memory device of claim 9, wherein the second conductive structures horizontally extend in the second direction beyond horizontal boundaries of the vertical stack structure.

15. The memory device of claim 9, further comprising:
an additional vertical stack structure comprising additional vertical conductive structures horizontally extending through additional vertical stacks of memory cells of each of the first memory array region and the second memory array region; and
an additional staircase structure comprising:
a portion of the additional vertical stack structure horizontally extending through the staircase region; and
additional sub-staircase structures horizontally extending from the additional vertical stack structure.

16. The memory device of claim 9, wherein a horizontal distance from a center of the staircase structure to the first memory array is about equal to a horizontal distance from the center of the staircase structure to the second memory array.

17. An electronic system, comprising:
an input device;
an output device;
a processor device operably coupled to the input device and the output device; and
a memory device operably coupled to the processor device and comprising:
a first microelectronic device structure comprising:
a first array region comprising first vertical stacks of memory cells comprising first vertical stacks of access devices horizontally neighboring first vertical stacks of access devices;
a second array region comprising second vertical stacks of memory cells comprising second vertical stacks of access devices horizontally neighboring second vertical stacks of access devices;
a staircase region horizontally between the first array region and the second array region and comprising staircase structures, at least one of the staircase structures comprising:
a vertical stack comprising first conductive structures horizontally extending through the staircase region and through the first array region and the second array region; and
sub-staircase structures comprising second conductive structures horizontally extending substantially perpendicular to the vertical stack, the sub-staircase structures individually comprising steps vertically descending in a horizontal direction extending away from the vertical stack and defined by edges of the second conductive structures; and
conductive contact structures individually in contact with one of the second conductive structures at the steps; and
a second microelectronic device structure attached to the first microelectronic device structure, the second microelectronic device structure comprising:
sub word line drivers vertically above the sub-staircase structures and within horizontal boundaries of the staircase region, the sub word line drivers individually operably coupled to the first vertical stacks of memory cells and the second vertical stacks of memory cells by means of the conductive contact structures.

18. The electronic system of claim 17, wherein the steps of the sub-staircase structures are vertically offset from one another.

19. The electronic system of claim 17, wherein a horizontal dimension of each of the sub-staircase structures is substantially the same.

20. The electronic system of claim 17, wherein a horizontal distance between a vertically uppermost one of the steps and the first array region is about the same as a horizontal distance between a vertically lowermost one of the steps and the second array region.
